(19) United States
(12) Patent Application Publication
(10) Pub. No.: US 2013/0134574 A1
(43) Pub. Date: May 30, 2013

(54) SEMICONDUCTOR DEVICE AND METHOD FOR FABRICATING THE SAME

(71) Applicant: FUJITSU SEMICONDUCTOR LIMITED, Yokohama-shi (JP)

(72) Inventor: Takumi Ihara, Tachikawa (JP)

(73) Assignee: FUJITSU SEMICONDUCTOR LIMITED, Yokohama-shi (JP)

(21) Appl. No.: 13/668,623

(22) Filed: Nov. 5, 2012

(30) Foreign Application Priority Data
Nov. 25, 2011 (JP) 2011-257128

(51) Int. Cl. H01L 23/36; H01L 21/50

(52) U.S. Cl. 257/706; 438/122; 257/E21.499; 257/E23.101

(57) ABSTRACT

A semiconductor device includes a semiconductor element placed over a substrate, a heat conducting material placed over the semiconductor element, and a radiator placed over the heat conducting material. The radiator has a plurality of projections which are arranged outside a region opposite to the semiconductor element and which protrude toward the substrate. Even if the heat conducting material flows out from over the semiconductor element at fabrication time, the heat conducting material which flows out is made by the plurality of projections to adhere to and spread along the radiator. As a result, the outflow or scattering of the heat conducting material toward the substrate or an electric trouble caused by it is prevented.

### CROSS-REFERENCE TO RELATED APPLICATION

This application is based upon and claims the benefit of priority of the prior Japanese Patent Application No. 2011-257128, filed on Nov. 25, 2011, the entire contents of which are incorporated herein by reference.

### FIELD

The embodiments discussed herein are related to a semiconductor device and a semiconductor device fabrication method.

### BACKGROUND

The technique of connecting a radiator, such as a heat spreader or a heat sink, to a semiconductor element included in a semiconductor device via a heat conducting material, such as solder or an adhesive, and radiating heat generated by the semiconductor element by the use of the radiator is known.

For example, methods for assembling such a semiconductor device are as follows. A heat conducting material, such as solder, placed between a semiconductor element and a radiator is heated, melted, and then solidified. A semiconductor element and a radiator are glued with a heat conducting material such as an adhesive.

With a semiconductor device assembled in this way, the technique of, for example, fixing a frame-like isolation section which surrounds a semiconductor element onto a radiator and holding inside the isolation section a heat conducting material which flows at assembly time is known. In addition, the technique of forming a concave portion (groove) in a region of a radiator opposite to a semiconductor element or along its circumference and holding in the concave portion a heat conducting material which flows is known.
Japanese Laid-open Patent Publication No. 2007-234781
Japanese Laid-open Patent Publication No. 2007-258448
Japanese Laid-open Patent Publication No. 10-294403
Japanese Laid-open Utility Model Publication No. 05-11470

With a semiconductor device in which a semiconductor element and a radiator are connected by the use of a heat conducting material, the heat conducting material which flows at, for example, assembly time may flow out of the semiconductor element or scatter as a result of a burst after the outflow. The heat conducting material which flows out or scatters may cause an electric trouble, such as a short circuit, in the semiconductor device. Even if a portion which holds or stores a heat conducting material that flows is formed on or in a radiator, the heat conducting material may flow out of a semiconductor element or scatter as a result of a burst. This may cause an electric trouble.

### SUMMARY

According to an aspect, there is provided a semiconductor device including a substrate, a semiconductor element placed over the substrate, a heat conducting material placed over the semiconductor element, and a radiator placed over the heat conducting material, the radiator having a plurality of projections which are arranged outside a region opposite to the semiconductor element and which protrude toward the substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are an example of a semiconductor device according to a first embodiment;

FIGS. 2A and 2B are views for describing an example of a substrate preparation step in the first embodiment;

FIGS. 3A and 3B are views for describing an example of a semiconductor element and electronic components mounting step in the first embodiment;

FIGS. 4A and 4B are views for describing an example of an under-fill resin filling step in the first embodiment;

FIGS. 5A and 5B are views for describing an example of a sealing material alignment step in the first embodiment;

FIGS. 6A and 6B are views for describing an example of a sealing step in the first embodiment;

FIGS. 7A and 7B are views for describing an example of a ball mounting step in the first embodiment;

FIGS. 8A and 8B are an example of a state in which a heat conducting material flows out in the sealing step (part 1);

FIGS. 9A and 9B are an example of a state in which a heat conducting material flows out in the sealing step (part 2);

FIGS. 10A and 10B are an example of a state in which a heat conducting material flows out in the sealing step (part 3);

FIGS. 11A and 11B are an example of a state in which a heat conducting material flows out in the sealing step (part 4);

FIGS. 12A and 12B are an example of a state in which a heat conducting material flows out in the sealing step (part 5);

FIGS. 13A, 13B, 13C, and 13D are schematic sectional views of the step of assembling a semiconductor device having another structure;

FIG. 14 is a schematic plan view of the semiconductor device having another structure;

FIG. 15 is an example of a state of a heat conducting material in the step of assembling the semiconductor device having another structure (part 1);

FIG. 16 is an example of a state of a heat conducting material in the step of assembling the semiconductor device having another structure (part 2);

FIG. 17 is an example of a state of a heat conducting material in the step of assembling the semiconductor device having another structure (part 3);

FIG. 18 is an example of a state of a heat conducting material in the step of assembling the semiconductor device having another structure (part 4);

FIGS. 19A and 19B are schematic sectional views of an example of an assembly step;

FIG. 20 is a schematic sectional view of a semiconductor device having still another structure;

FIGS. 21A and 21B are views for describing a case in which a nonconductive material is used as a heat conducting material (part 1);

FIGS. 22A and 22B are views for describing a case in which a nonconductive material is used as a heat conducting material (part 2);

FIGS. 23A, 23B, and 23C are examples of the shape of projections formed on a radiator (part 1);

FIGS. 24A, 24B, and 24C are examples of the shape of projections formed on a radiator (part 2);

FIGS. 25A, 25B, and 25C are examples of a semiconductor device which differ in the height of projections on a radiator;

FIGS. 26A and 26B are an example of a semiconductor device according to a second embodiment;

FIG. 27 is a schematic sectional view of an example of the step of assembling the semiconductor device according to the second embodiment;

FIGS. 28A and 28B are an example of a semiconductor device according to a third embodiment;

FIGS. 29A and 29B are another example of the semiconductor device according to the third embodiment;

FIGS. 30A and 30B are an example of a semiconductor device according to a fourth embodiment;

FIGS. 31A and 31B are an example of a semiconductor device according to a fifth embodiment;

FIGS. 32A and 32B are schematic sectional views of an example of the step of assembling the semiconductor device according to the fifth embodiment;

FIGS. 33A and 33B are another example of the semiconductor device according to the fifth embodiment (part 1);

FIGS. 34A and 34B are another example of the semiconductor device according to the fifth embodiment (part 2); and

FIG. 35 is an example of a semiconductor device using a plate-like radiator.

### DESCRIPTION OF EMBODIMENTS

A first embodiment will be described first.

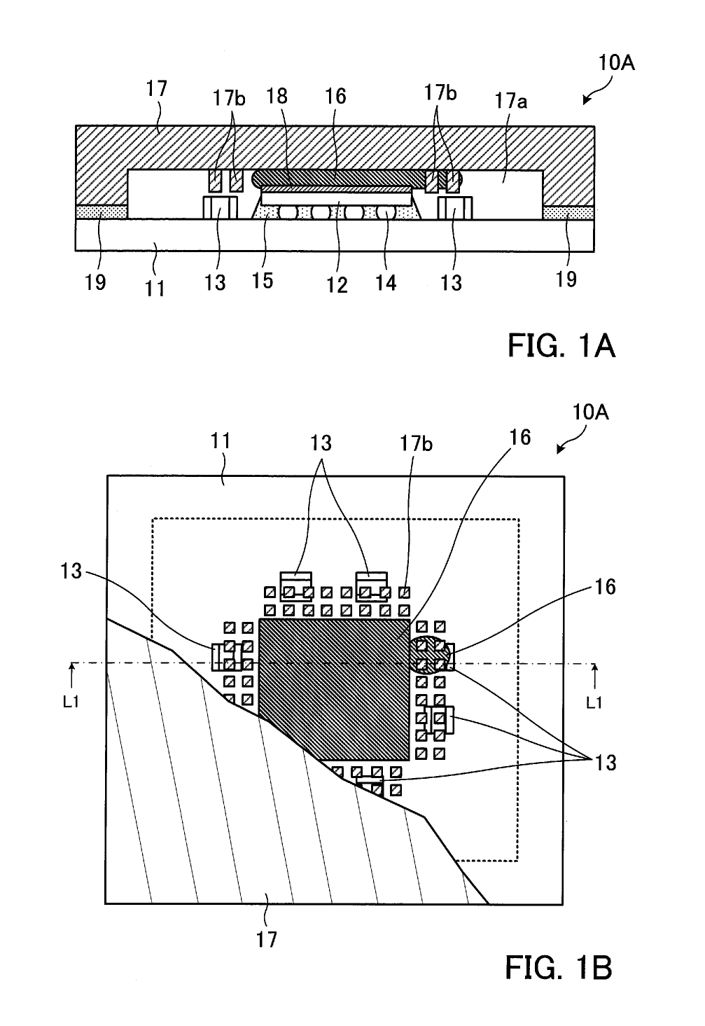

FIGS. 1A and 1B are an example of a semiconductor device according to a first embodiment. FIG. 1B is a schematic plan view of an example of a semiconductor device according to a first embodiment. FIG. 1A is a schematic sectional view taken along lines L1-L1 of FIG. 1B.

A semiconductor device 10A according to a first embodiment includes a substrate (wiring substrate) 11 and a semiconductor element (semiconductor chip) 12 and electronic components 13 mounted on the substrate 11.

Each of the substrate 11 and the semiconductor element 12 has an electrode pad (not illustrated in FIG. 1A or 1B) on its surface opposite to the other. The electrode pad of the substrate 11 is electrically connected to conductive portions (not illustrated), such as wirings or vias, formed in the substrate 11. The electrode pad of the semiconductor element 12 is connected to the electrode pad of the substrate 11 via bumps 14 and the semiconductor element 12 is flip-chip-mounted on the substrate 11.

One or more (eight, in this example) electronic components 13 are mounted on electrode pad (not illustrated in FIG. 1A or 1B) formed outside a region of the substrate 11 in which the semiconductor element 12 is mounted by the use of a bonding member such as solder. Passive components, such as a chip capacitor, an LC filter, and a ferrite bead, are used as the electronic components 13.

Under-fill resin 15 is placed between the substrate 11 and the semiconductor element 12 and on sides of the semiconductor element 12.

A radiator 17 is placed over the surface of the substrate 11 over which the semiconductor element 12 is mounted with a heat conducting material 16 between. The semiconductor element 12 is thermally connected to the radiator 17 via the heat conducting material 16.

A material having thermal conductivity is used as the heat conducting material 16. In addition, it is desirable to use a material having good workability as the heat conducting material 16. For example, a metal material such as solder is used as the heat conducting material 16. If solder is used as the heat conducting material 16, various materials or compositions can be used. For example, indium (In) based solder, indium-silver (In—Ag) based solder, tin-lead (Sn—Pb) based solder, tin-bismuth (Sn—Bi) based solder, tin-silver (Sn—Ag) based solder, tin-antimony (Sn—Sb) based solder, tin-zinc (Sn—Zn) based solder, or the like can be used. In addition, a nonconductive material, such as resin, can be used as the heat conducting material 16.

A bonding layer 18 is formed on a top of the semiconductor element 12. The heat conducting material 16 is bonded to the semiconductor element 12 with the bonding layer 18 between. A metallized layer can be used as the bonding layer 18. For example, a laminated structure (Ti/Au) of a titanium (Ti) layer and a gold (Au) layer can be used as a metallized layer. Furthermore, a laminated structure (Ti/Ni—V/Au) of a Ti layer, a nickel-vanadium (Ni—V) layer, and an Au layer can be used as a metallized layer. These laminated structures can be formed by, for example, a sputtering method. In addition, a nickel (Ni) based plated layer, which is a metallized layer, can be used as the bonding layer 18 if it can be bonded to the heat conducting material 16.

By forming the bonding layer 18 on the top of the semiconductor element 12, an effect, such as an increase in the wettability of the heat conducting material 16 to (bonding layer 18 formed on the top of) the semiconductor element 12 or an increase in the strength of bonding between the heat conducting material 16 and the semiconductor element 12, can be obtained.

The radiator 17 has a concave portion 17a. The radiator 17 is placed over the substrate 11 so that the semiconductor element 12 and the electronic components 13 will be held in the concave portion 17a. The radiator 17 is bonded to the heat conducting material 16. For example, as illustrated in FIG. 1A, the radiator 17 is bonded not only to the heat conducting material 16 but also to the substrate 11 with an adhesive 19.

The radiator 17 has a plurality of projections 17b on the concave portion 17a. Each projection 17b is formed outside a region opposite to the semiconductor element 12 so that it will protrude toward the substrate 11 and so that it will not reach the substrate 11. If, as illustrated in FIG. 1A, the electronic components 13 are mounted in a direction in which each projection 17b protrudes, then each projection 17b is formed so that it will not reach an electronic component 13.

A highly radiative material having good thermal conductivity is used for making the radiator 17. For example, copper (Cu), aluminum (Al), aluminum silicon carbide (AlSiC), aluminum carbide (AlC), silicone rubber, or the like can be used for making the radiator 17. The radiator 17 can be formed by press working, molding, or the like.

A bonding layer may be formed in a region of the radiator 17 including the region opposite to the semiconductor element 12 (region to which the heat conducting material 16 is bonded). A metallized layer can be used as the bonding layer. For example, a laminated structure (Ni/Au) of an Ni layer and an Au layer can be used as a metallized layer. An Ni/Au laminated structure can be formed by a plating method or the like. In addition, an Sn layer, an Ag layer, or an Ni layer which is formed by the plating method or the like and which is a metallized layer may be used as the bonding layer if it can be bonded to the heat conducting material 16. Furthermore, a Cu layer, an Al layer, or the like may be used as the bonding layer, depending on a material for the radiator 17.

If the bonding layer is formed on the radiator 17, it is formed in the region opposite to the semiconductor element 12. In addition, the bonding layer may be formed on the surface of each projection 17b formed outside the region opposite to the semiconductor element 12 and a region in which the plurality of projections 17b are arranged.

By forming the above bonding layer in a determined region of the radiator 17, an effect, such as an increase in the wettability of the heat conducting material 16 to (bonding layer formed on) the radiator 17 or an increase in the strength of bonding between the heat conducting material 16 and the radiator 17, can be obtained.

The radiator 17 is bonded to the semiconductor element 12 (bonding layer 18) by the heat conducting material 16. As a result, the radiator 17 and the semiconductor element 12 are thermally connected via the heat conducting material 16.

Electrode pads (not illustrated) electrically connected to conductive portions in the substrate 11 is formed on a surface of the substrate 11 reverse to the surface over which the semiconductor element 12 is mounted. The semiconductor device 10A is mounted over another board (wiring board), such as a mother board or an interposer, via a connection member, such as a socket or a solder ball, connected to the electrode pad.

A conductive material, such as Cu or Al, can be used for forming the electrode pads and the internal conductive portions (wirings and vias) of the substrate 11.

When the semiconductor device 10A having the above structure operates, the semiconductor element 12 generates heat. With the semiconductor device 10A the semiconductor element 12 and the radiator 17 are thermally connected via the heat conducting material 16 and the like. Heat generated by the semiconductor element 12 is efficiently transferred to the radiator 17 via the heat conducting material 16. This prevents the semiconductor element 12 from overheating and malfunction of or damage to the semiconductor element 12 caused by overheat is prevented.

Furthermore, even if the heat conducting material 16, such as solder, having fluidity flows out at the time of, for example, assembling the semiconductor device 10A having the above structure, it is possible to make the heat conducting material 16 which flows out adhere to and spread along the surface of the radiator 17 on which the plurality of projections 17b are arranged. Accordingly, the possibility that the heat conducting material 16 which flows out adheres to an electronic component 13 or the substrate 11 or the possibility that the heat conducting material 16 which scatters as a result of a burst adheres to an electronic component 13 or the substrate 11 does not arise. That is to say, an electric trouble, such as a short circuit, in the semiconductor device 10A which occurs for these reasons can effectively be prevented. This point, together with an example of a method for fabricating (assembling) the semiconductor device 10A, will now be described in further detail.

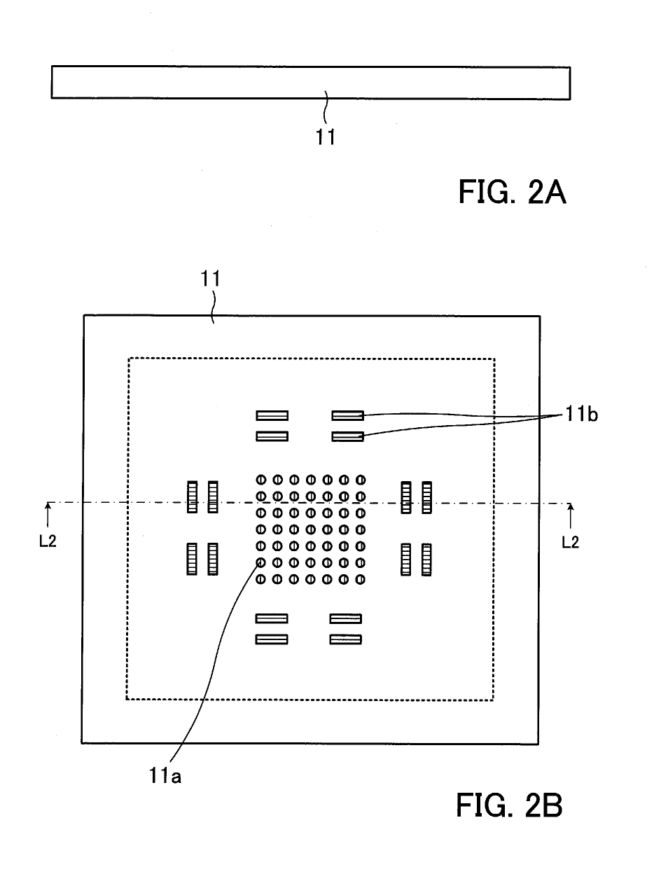

FIGS. 2A and 2B are views for describing an example of a substrate preparation step in the first embodiment. FIG. 2B is a schematic plan view of an example of a substrate preparation step in the first embodiment. FIG. 2A is a schematic sectional view taken along lines L2-L2 of FIG. 2B.

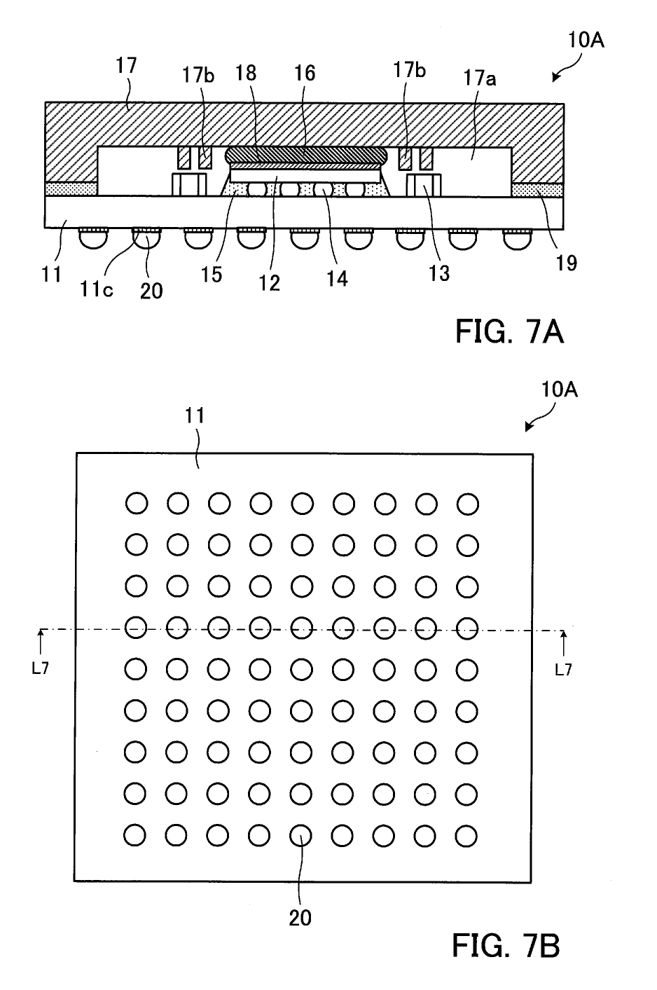

In order to fabricate the semiconductor device 10A, first the substrate 11 illustrated in FIGS. 2A and 2B is prepared. Conductive portions (not illustrated), such as wirings of determined patterns and vias by which the wirings are connected, are formed in the substrate 11. As illustrated in FIG. 2B, electrode pads 11a and electrode pads lib are formed on one surface of the substrate 11. The electrode pads 11a are formed in a region in which the semiconductor element 12 is mounted. The electrode pads 11b are formed in a region in which the electronic components 13 are mounted. This region is outside the region in which the semiconductor element 12 is mounted. Furthermore, electrode pads for connecting the semiconductor device 10A to the outside are formed on the other surface of the substrate 11 (FIGS. 7A and 7B). In addition, a wiring of a determined pattern or an electrode pad, such as a test pad, may be formed on a surface of the substrate 11.

The semiconductor element 12 and the electronic components 13 are mounted over the above substrate 11.

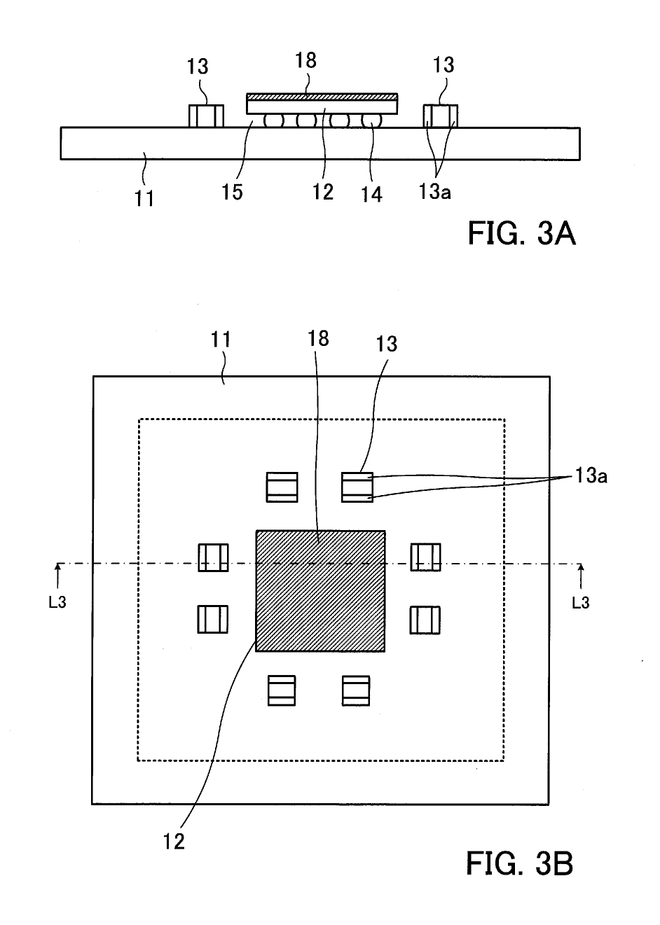

FIGS. 3A and 3B are views for describing an example of a semiconductor element and electronic components mounting step in the first embodiment. FIG. 3B is a schematic plan view of an example of a semiconductor element and electronic components mounting step in the first embodiment. FIG. 3A is a schematic sectional view taken along lines L3-L3 of FIG. 3B.

The following semiconductor element 12 to be mounted is prepared. Bumps 14 are formed on electrode pads formed on a surface of the semiconductor element 12. A bonding layer 18 is formed on a surface of the semiconductor element 12 reverse to the surface over which the bumps 14 are formed. Alignment of the bumps 14 of the semiconductor element 12 with the electrode pads 11a of the substrate 11 is performed and the bumps 14 are connected to the electrode pads 11a. By doing so, the semiconductor element 12 is flip-chip-mounted over the substrate 11. For example, a flip chip bonder can be used for mounting the above semiconductor element 12.

The height of the semiconductor element 12 mounted over the substrate 11 is, for example, 0.610 mm (thickness of the semiconductor element 12 is 0.550 mm and the thickness of the bumps 14 is 0.060 mm). However, this height depends on the type of the semiconductor element 12. In this example, chip capacitors are used as the electronic components 13 to be mounted. The above electrode pads 11b are formed on the substrate 11 to a pair of electrodes 13a of each of these chip capacitors. Electrodes 13a of each electronic component 13 are connected to electrode pads 11b by the use of a conductive bonding material such as solder (not illustrated in FIG. 3A or 3B) and each electronic component 13 is mounted over the substrate 11.

After the semiconductor element 12 and the electronic components 13 are mounted, filling is performed by the use of the under-fill resin 15.

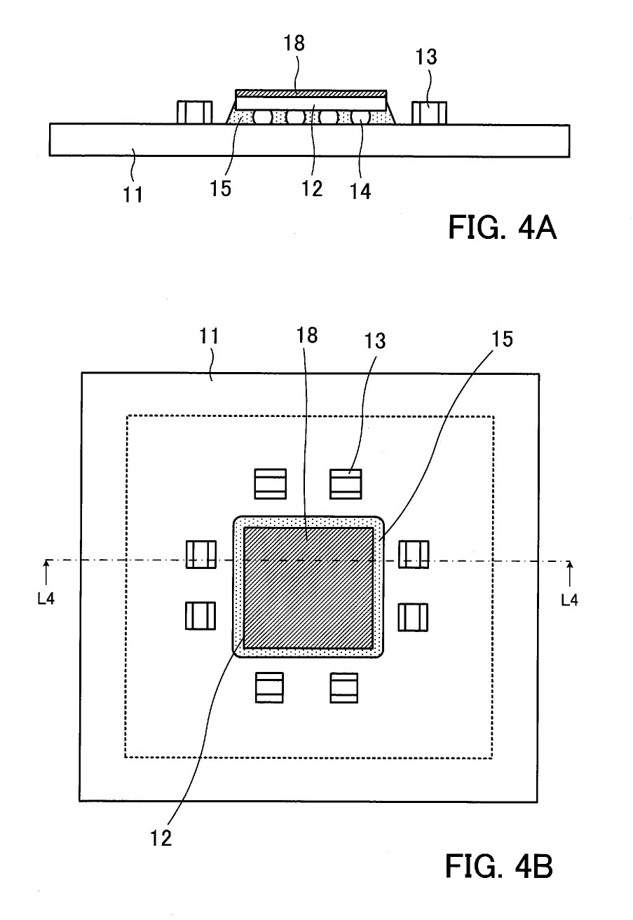

FIGS. 4A and 4B are views for describing an example of an under-fill resin filling step in the first embodiment. FIG. 4B is a schematic plan view of an example of an under-fill resin filling step in the first embodiment. FIG. 4A is a schematic sectional view taken along lines L4-L4 of FIG. 4B.

The under-fill resin 15 is injected into a space between the substrate 11 and the semiconductor element 12 mounted over the substrate 11, the space is filled with the under-fill resin 15, and the under-fill resin 15 is hardened. The under-fill resin 15 may also be placed on the sides of the semiconductor element 12. By placing the under-fill resin 15, the substrate 11 and the semiconductor element 12 are connected firmly and the reliability of the connection between them is improved. After that, alignment of sealing materials used for sealing the semiconductor element 12 and the electronic components 13 mounted in this way over the substrate 11 is performed.

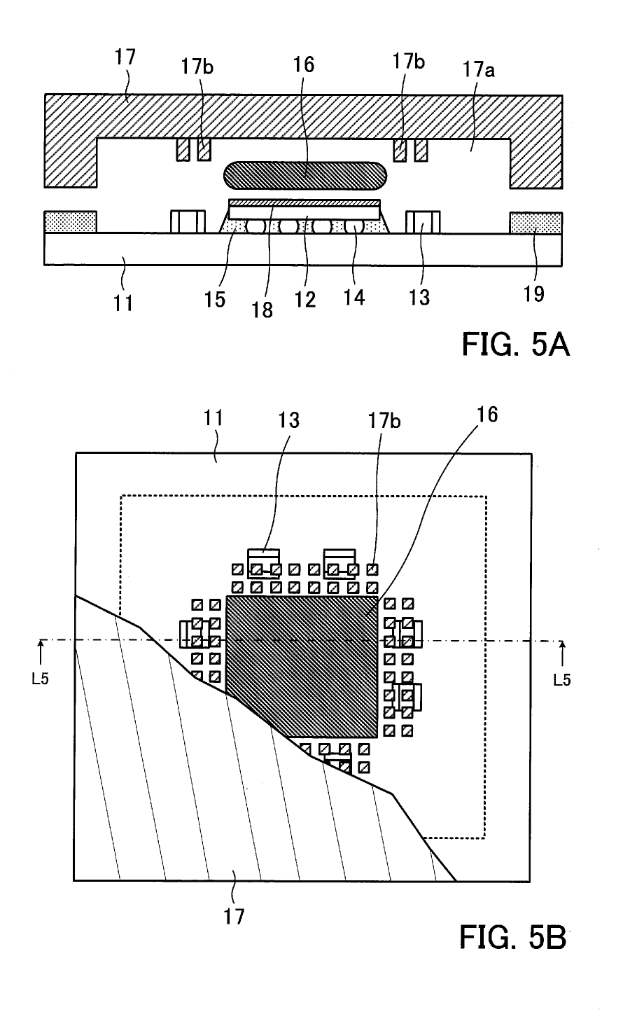

FIGS. 5A and 5B are views for describing an example of a sealing material alignment step in the first embodiment. FIG. 5B is a schematic plan view of an example of a sealing material alignment step in the first embodiment. FIG. 5A is a schematic sectional view taken along lines L5-L5 of FIG. 5B.

In this sealing material alignment step, the substrate 11 over which the semiconductor element 12 and the electronic components 13 are mounted and the radiator 17 are placed with the heat conducting material 16 between. The heat conducting material 16 is placed between the semiconductor element 12 (bonding layer 18) mounted over the substrate 11 and the radiator 17 (region inside the region in which the plurality of projections 17b are arranged). The adhesive 19 is placed between an edge portion of the radiator 17 and the substrate 11. For example, a thermosetting resin is used as the adhesive 19.

Description will be given with a case where solder is used as the heat conducting material 16 as an example. In this case, the heat conducting material 16 worked in advance into a shape corresponding to the plane (external) size of the semiconductor element 12 is prepared. The following radiator 17 is prepared. The concave portion 17a which holds the semiconductor element 12 and the electronic components 13 is formed. The plurality of projections 17b are formed in a region of the concave portion 17a outside the region opposite to the semiconductor element 12. A bonding lay (not illustrated) may be formed in advance in the region of the radiator 17 opposite to the semiconductor element 12 and on the plurality of projections 17b by the use of a determined material according to, for example, materials for the heat conducting material 16, the radiator 17, and the plurality of projections 17b.

After the heat conducting material 16, the radiator 17, and the adhesive 19 are placed as illustrated in FIG. 5A, sealing is performed by the use of them.

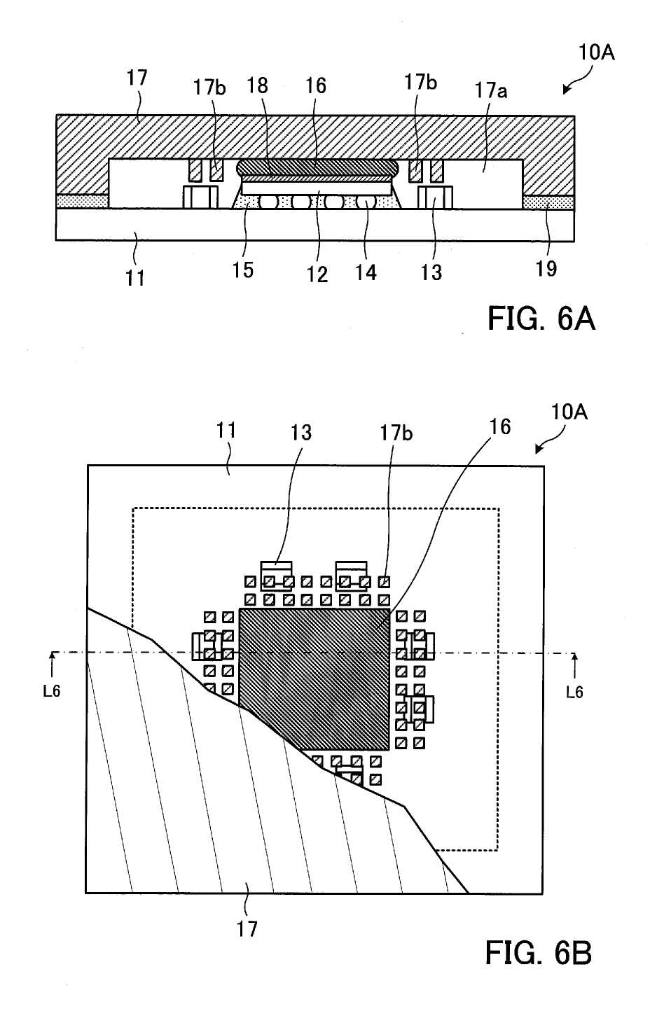

FIGS. 6A and 63 are views for describing an example of a sealing step in the first embodiment. FIG. 6B is a schematic plan view of an example of a sealing step in the first embodiment. FIG. 6A is a schematic sectional view taken along lines L6-L6 of FIG. 6B.

As stated above, at sealing time the radiator 17 is placed so that solder used as the heat conducting material 16 will be between the semiconductor element 12 mounted over the substrate 11 and the radiator 17. At the same time that the radiator 17 is being heated, the radiator 17 is pressed toward the substrate 11. Furthermore, the substrate 11 is pressed toward the radiator 17. Heating temperature at which the radiator 17 and the substrate 11 are pressed is temperature at which solder used as the heat conducting material 16 melts. By pressing the radiator 17 and the substrate 11 in this way while heating the radiator 17, the radiator 17 is bonded to the semiconductor element 12 with the heat conducting material 16 and the radiator 17 is adhered to the substrate 11 with the adhesive 19.

The semiconductor element 12 may warp (semiconductor element 12 may become convex on the radiator 17 side) because of the difference in rate of thermal expansion between the semiconductor element 12 and the substrate 11 (not illustrated). Even in that case, in order to bond the heat conducting material 16 to the entire semiconductor element 12, pressing is performed so as to press the semiconductor element 12 from above and below as illustrated in FIG. 6A. The height of the heat conducting material 16 (thickness of the semiconductor device 10A after assembly) is, for example, 0.280 mm.

After sealing is performed in the above way, an assembled structure after the sealing is cooled to, for example, room temperature and solder used as the heat conducting material 16 is solidified. As a result, a form of the semiconductor device 10A (LGA (Land Grid Array) type semiconductor device 10A) is obtained. In addition, as illustrated in FIGS. 7A and 7B, solder balls 20 may be mounted over the semiconductor device 10A.

FIGS. 7A and 7B are views for describing an example of a ball mounting step in the first embodiment. FIG. 7B is a schematic plan view of an example of a ball mounting step in the first embodiment from a surface over which balls are mounted. FIG. 7A is a schematic sectional view taken along lines L7-L7 of FIG. 7B.

As illustrated in FIGS. 7A and 7B, the solder balls 20 are mounted on electrode pads 11c formed on the surface of the substrate 11 reverse to the surface over which the semiconductor element 12 is mounted. By mounting the solder balls 20 in this way over the substrate 11, the BGA (Ball Grid Array) type semiconductor device 10A may be obtained.

The semiconductor device 10A can be assembled by the above steps. However, when the above assembly is performed, the heat conducting material 16 having fluidity may flow out from over the semiconductor element 12 after the above alignment illustrated in FIGS. 5A and 5B at the time of the sealing by heating and pressing illustrated in FIGS. 6A and 6B.

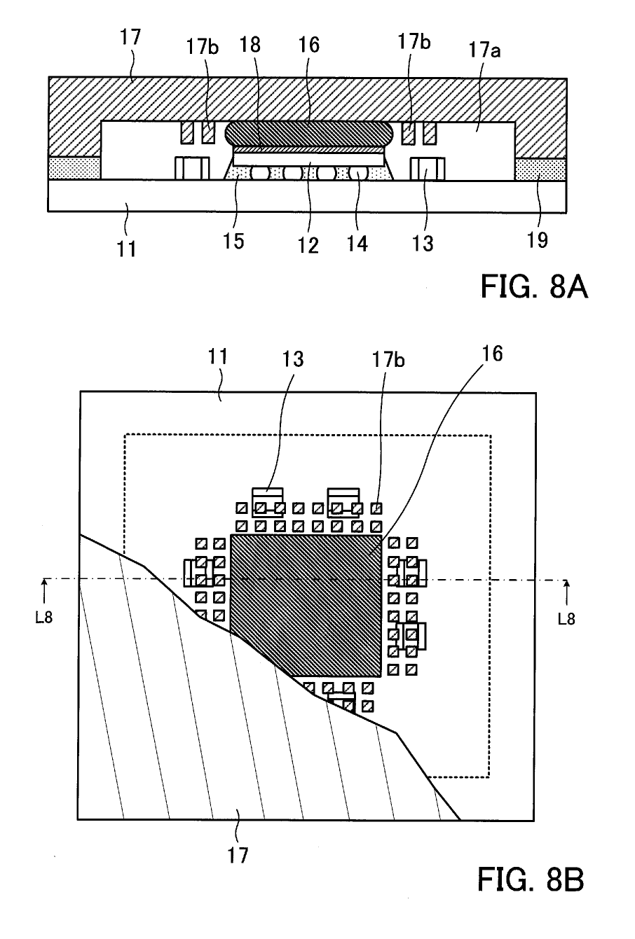

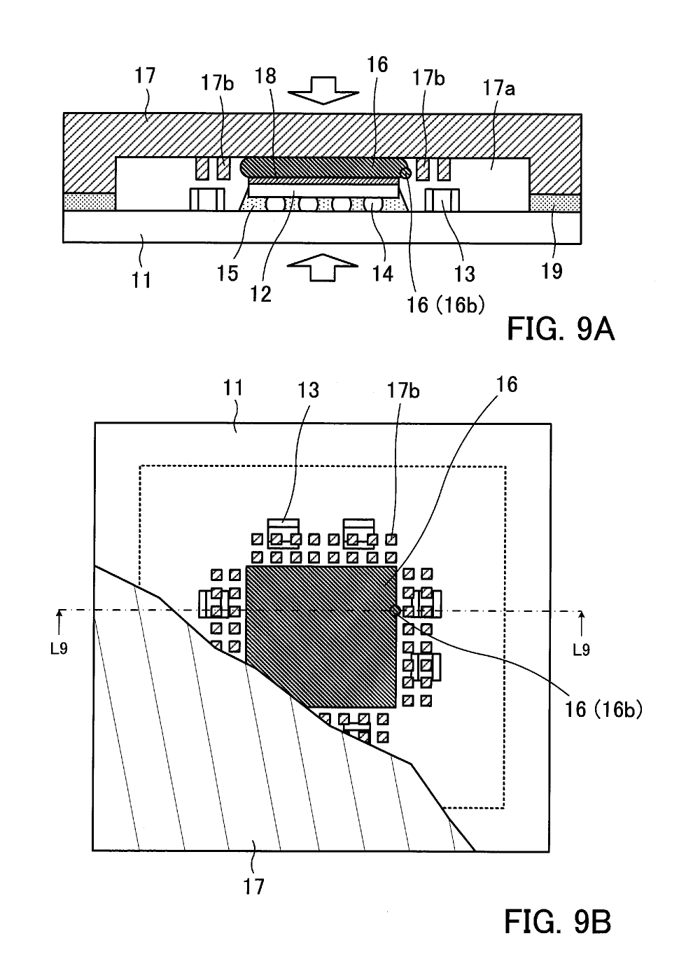

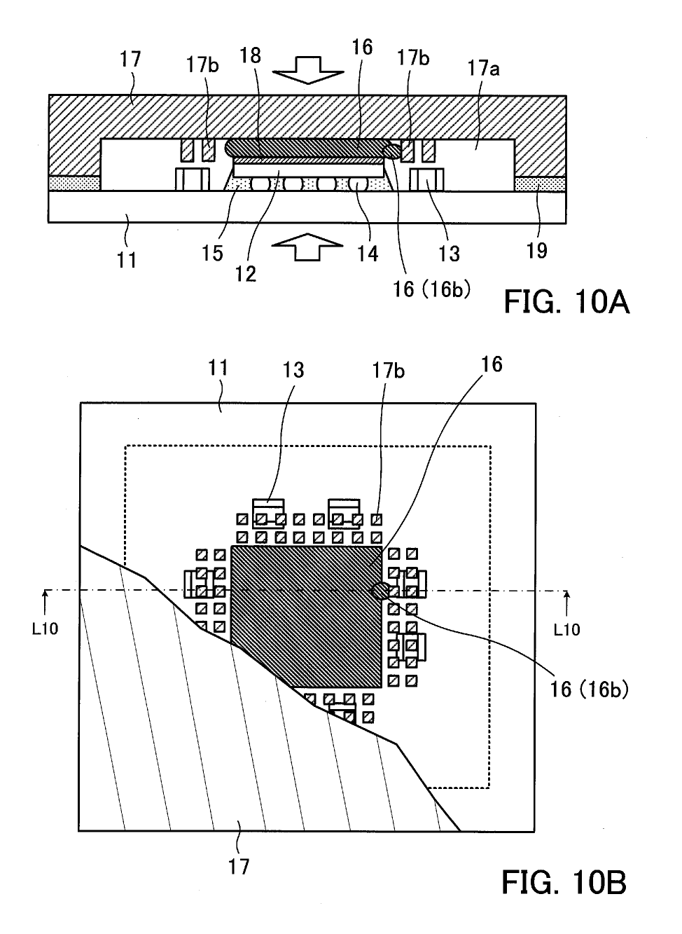

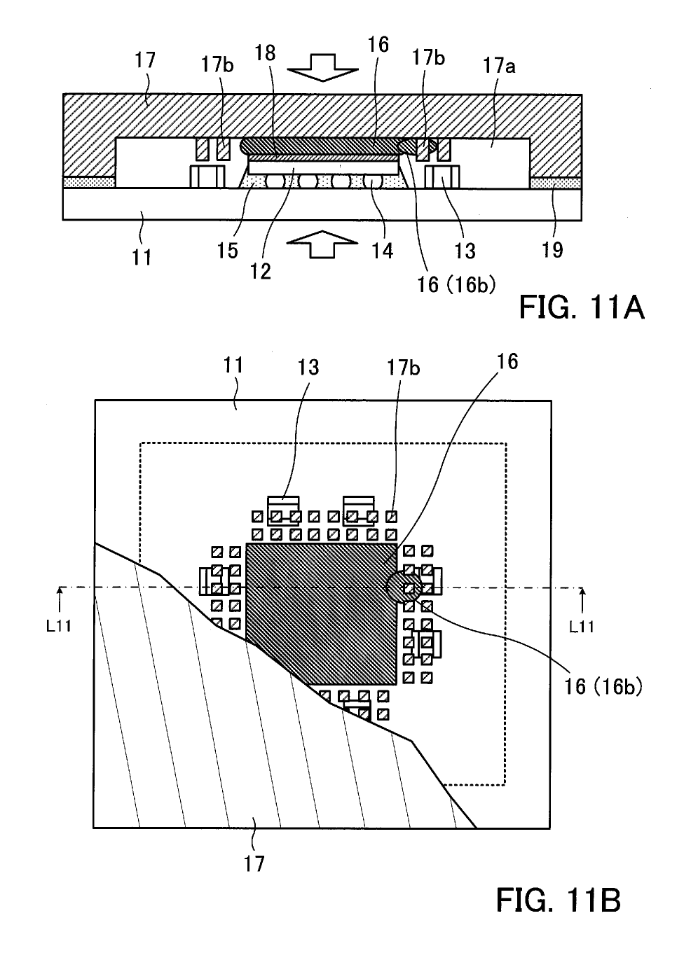

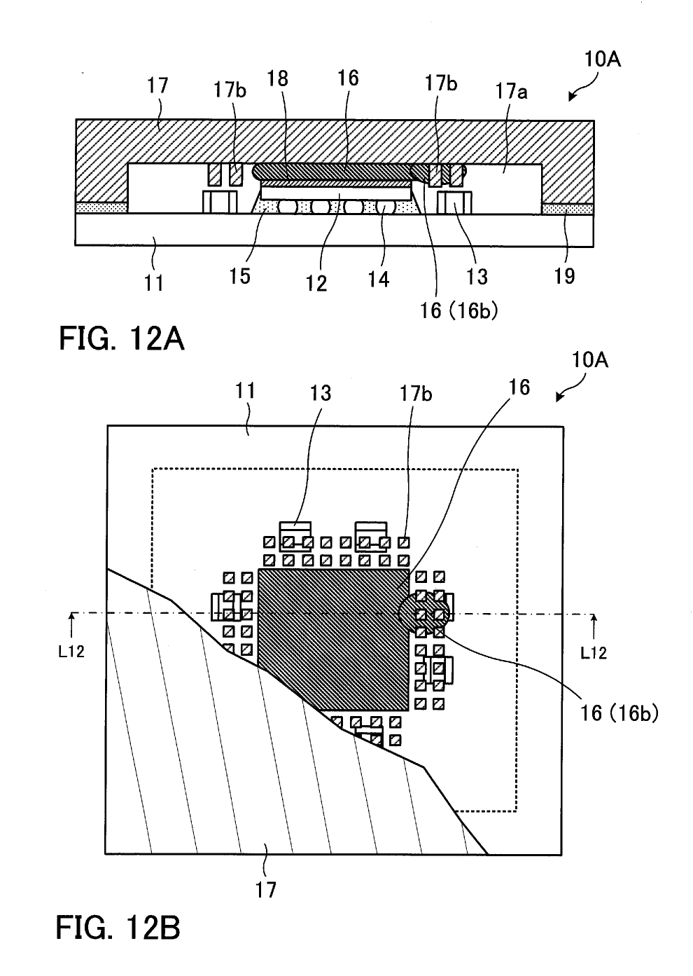

FIGS. 8A and 8B through 12A and 12B are an example of a state in which the heat conducting material flows out in the sealing step. FIG. 8B is a schematic plan view of an example of a state in which the heat conducting material flows out in the sealing step. FIG. 8A is a schematic sectional view taken along lines L8-L8 of FIG. 8B. FIG. 9B is a schematic plan view of an example of a state in which the heat conducting material flows out in the sealing step. FIG. 9A is a schematic sectional view taken along lines L9-L9 of FIG. 9B. FIG. 10B is a schematic plan view of an example of a state in which the heat conducting material flows out in the sealing step. FIG. 10A is a schematic sectional view taken along lines L10-L10 of FIG. 10B. FIG. 11B is a schematic plan view of an example of a state in which the heat conducting material flows out in the sealing step. FIG. 11A is a schematic sectional view taken along lines L11-L11 of FIG. 11B. FIG. 12B is a schematic plan view of an example of a state in which the heat conducting material flows out in the sealing step. FIG. 12A is a schematic sectional view taken along lines L12-L12 of FIG. 12B.

As illustrated in FIGS. 8A and 8B, solder used as the heat conducting material 16 is between the semiconductor element 12 mounted over the substrate 11 and the radiator 17 and the adhesive 19 is between the edge portion of the radiator 17 and the substrate 11. As illustrated in FIGS. 9A and 9B through 12A and 12B, at the same time that the radiator 17 is being heated in this state, each of the radiator 17 and the substrate 11 is pressed toward the other.

As illustrated in FIGS. 9A and 9B, it is assumed that a part of the heat conducting material 16 which melts as a result of heating begins to flow out (protrude) in a comparatively early stage of pressing (outflow portion 16b). For example, as a result of heating and pressing, an oxide film formed on the surface of solder used as the heat conducting material 16 may rupture and pure solder inside the oxide film may flow out from a rupture. As a result, the state illustrated in FIGS. 9A and 9B arises.

In the state illustrated in FIGS. 9A and 9B, pressing is performed further with heating continued. By doing so, as illustrated in FIGS. 10A and 10B, the heat conducting material 16 is pressed both from the radiator side and from the semiconductor element 12 (substrate 11) side and an outflow of the heat conducting material 16 increases. At this time the heat conducting material 16 which flows out touches a projection 17b formed on the radiator 17, and adheres to it. Furthermore, when pressing is performed further, an outflow of the heat conducting material 16 increases as illustrated in FIGS. 11A and 11B. However, the heat conducting material 16 which flows out adheres to and spreads among projections 17b formed on the radiator 17 by capillarity. Pressing is performed further and cooling is performed in that state. As a result, as illustrated in FIGS. 12A and 12B, the heat conducting material 16 which flows out adheres to and spreads among projections 17b and is solidified.

By forming the plurality of projections 17b on the radiator 17, as stated above, it is possible to make the heat conducting material 16 which flows out as a result of heating and pressing adhere to and spread among projections 17b formed on the radiator 17 by utilizing capillarity. Accordingly, with the semiconductor device 10A adhesion of the heat conducting material 16 which flows out to an electronic component 13 or the substrate and an electric trouble caused by such adhesion can effectively be prevented.

Furthermore, after the heat conducting material 16 begins to flow out from over the semiconductor element 12, it touches a projection 17b formed on the radiator 17 in a comparatively early stage and adheres to the projection 17b. Accordingly, even after the heat conducting material 16 begins to flow out from over the semiconductor element 12 in the semiconductor device 10A, an oxide film on the surface of the heat conducting material 16 does not rupture. After the heat conducting material 16 flows out by a certain amount, an oxide film on the surface of the heat conducting material 16 ruptures. For example, the occurrence of the phenomenon of a burst and scattering about of the heat conducting material 16 which flows out can be avoided. Accordingly, adhesion of the heat conducting material 16 which scatters to an electronic component 13 or the substrate 11 and an electric trouble caused by such adhesion can effectively be prevented.

When the heat conducting material 16 flows out, the heat conducting material 16 flows into a space between projections 17b by capillarity and gradually adheres to and spreads among the projections 17b. Accordingly, a portion of the heat conducting material 16 which flows out is unapt to take air in, and a void is unapt to appear. Even if a void (which is not large enough to cause a burst) appears in the portion of the heat conducting material 16 which flows into a region in which the projections 17b are formed, the outflow portion which contains the void is outside the semiconductor element 12 which generates heat at the time of the operation of the semiconductor device 10A. Therefore, compared with a case where a void appears in a portion of the heat conducting material 16 between the semiconductor element 12 and the radiator 17, the influence on heat transfer from the semiconductor element 12 to the radiator 17 and heat radiation from the radiator 17 to the outside can be curbed.

As has been described, the high-quality high performance semiconductor device 10A in which an electric trouble caused by the outflow and a burst of the heat conducting material 16 is prevented can be realized.

In FIGS. 5A and 5B, FIGS. 6A and 6B, and FIGS. 8A and 8B through 12A and 128, assembly is performed by placing the substrate 11 on a lower side, placing the radiator 17 on an upper side, and placing the heat conducting material 16 between them. In addition, assembly can be performed by placing the radiator 17 on a lower side, placing the substrate 11 on an upper side, and placing the heat conducting material 16 between them.

In this case, the semiconductor device 10A is assembled in, for example, the following way. First the heat conducting material 16 is placed over the radiator 17 placed with the concave portion 17a and the plurality of projections 17b upward. At this time the heat conducting material 16 is placed inside a region in which the plurality of projections 17b are formed. The substrate 11 over which the semiconductor element 12 and the electronic components 13 are mounted and over which the adhesive 19 is placed is placed over the radiator 17 over which the heat conducting material 16 is placed in this way. At the same time that heating is being performed at a determined temperature, each of the substrate 11 and the radiator 17 is then pressed toward the other. The semiconductor device 10A can also be assembled by this method. Furthermore, at this time scattering of the heat conducting material 16 due to the outflow and a burst of the heat conducting material 16 is avoided by the plurality of projections 17b formed on the radiator 17. An electric trouble caused by adhesion of the heat conducting material 16 to an electronic component 13 or the substrate 11 can effectively be prevented. This is the same with the above case.

For comparison, a semiconductor device having another structure, that is to say, a semiconductor device using a radiator on which projections like those described above are not formed and an example of a method for assembling such a semiconductor device will now be described.

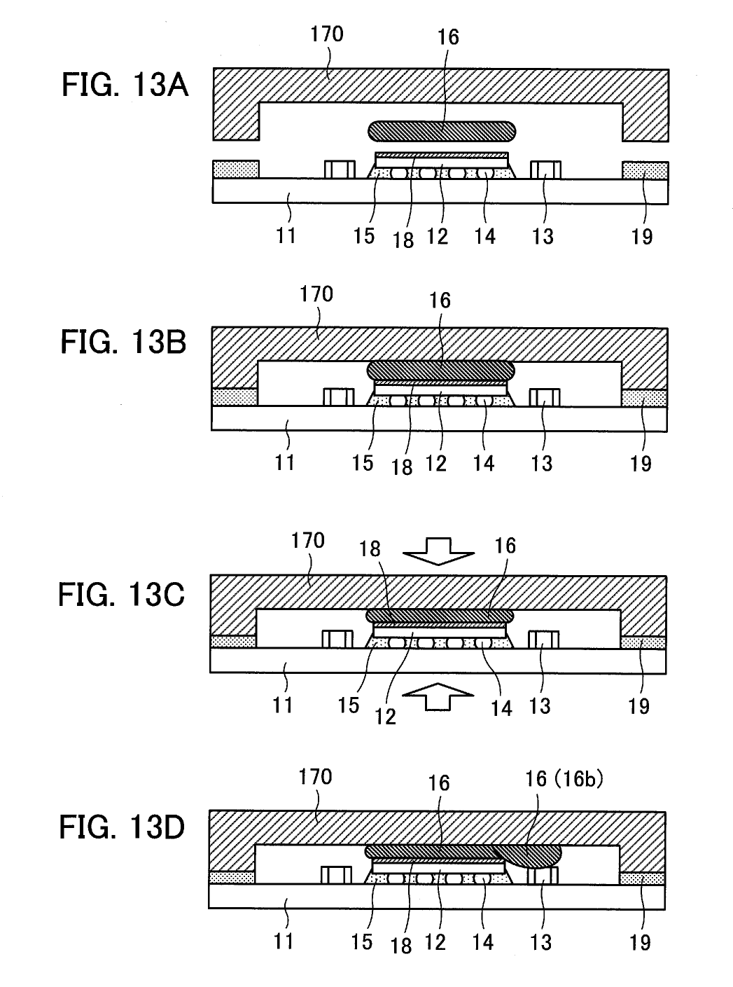

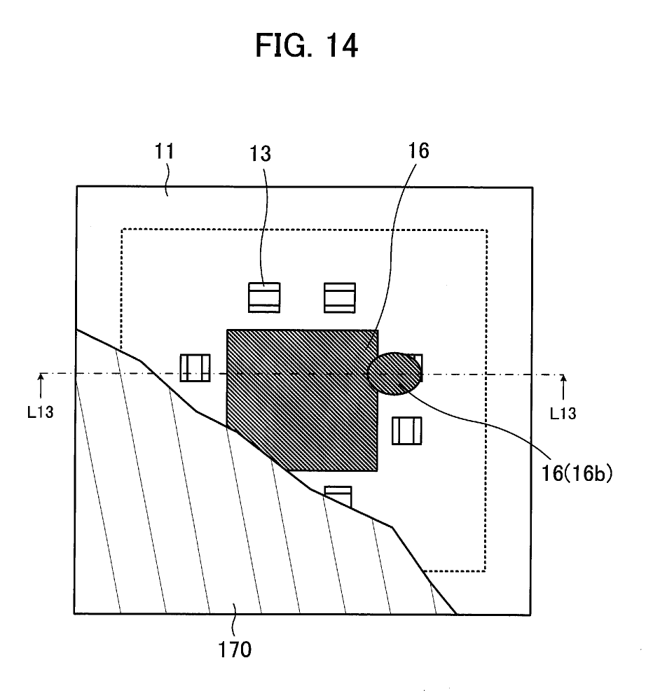

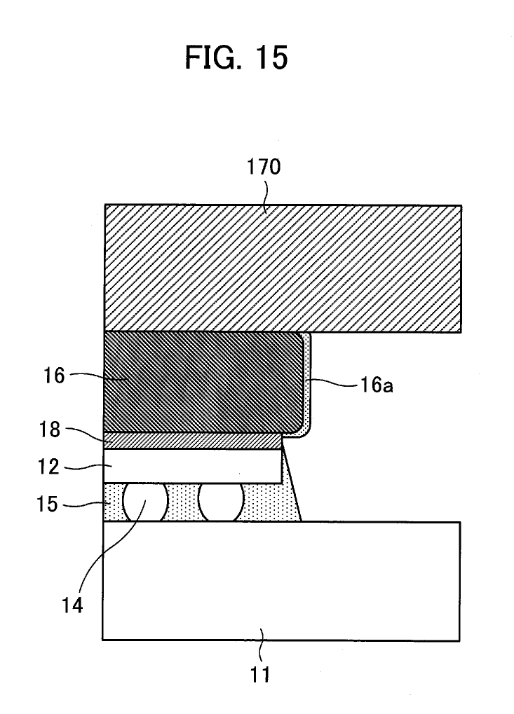

FIGS. 13A, 13B, 13C, and 13D are schematic sectional views of the step of assembling a semiconductor device having another structure. FIG. 14 is a schematic plan view of the semiconductor device having another structure. FIGS. 15 through 18 are examples of a state of a heat conducting material in the step of assembling the semiconductor device having another structure. FIG. 13D is a schematic sectional view taken along lines L13-L13 of FIG. 14. FIGS. 15 through 18 are fragmentary schematic sectional views of the vicinity of an outflow portion of a heat conducting material.

As illustrated in FIG. 13A, first a heat conducting material 16, such as solder, is placed between a substrate 11 over which a semiconductor element 12 and electronic components 13 (chip capacitors, in this example) are mounted and a radiator 170 not having a projection, and alignment is performed. For example, a thermosetting adhesive 19 is placed in a region of the substrate 11 to which an edge portion of the radiator 170 is adhered.

As illustrated in FIG. 13B, the heat conducting material 16, which is solder, is then put between the radiator 170 and the semiconductor element 12 and is fixed. As illustrated in FIG. 15, usually an oxide film 16a is formed on the surface of the heat conducting material 16, which is solder. In FIG. 15, the oxide film 16a is illustrated only on a side of the heat conducting material 16. However, the oxide film 16a may also be formed between the heat conducting material 16 and a bonding layer 18 and between the heat conducting material 16 and the radiator 170 (or a bonding layer, if it is formed on the radiator 170).

As illustrated in FIG. 13C, at the same time that heating is being performed at a temperature at which the heat conducting material 16, which is solder, melts, each of the radiator 170 and the substrate 11 is then pressed toward the other. By performing heating and pressing in this way, the radiator 170 is bonded to the semiconductor element 12 (bonding layer 18) with the heat conducting material 16 and the radiator 170 is adhered to the substrate 11 with the adhesive 19.

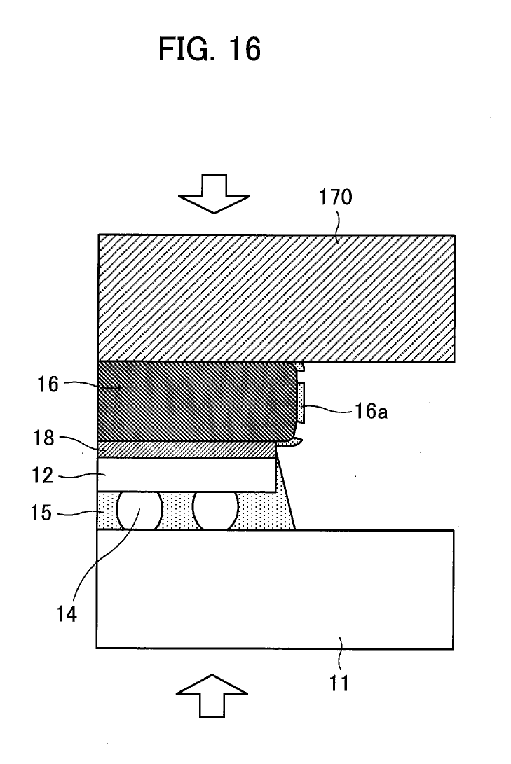

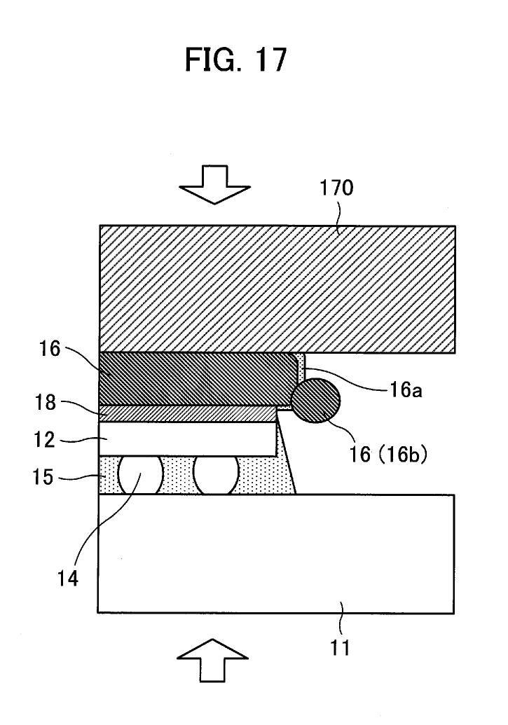

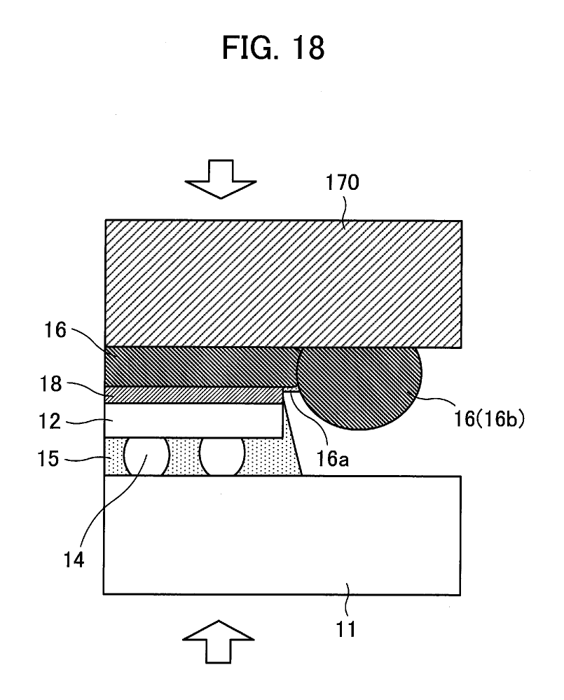

As illustrated in FIG. 16, when the heat conducting material 16, which is solder, melts in this stage of heating and pressing, the oxide film 16a formed on the surface of the heat conducting material 16 ruptures due to a change in shape or by internal extrusive force. As a result, as illustrated in FIG. 17, internal pure solder flows out through a rupture in the oxide film 16a (outflow portion 16b). An outflow of the heat conducting material 16 through the rupture in the oxide film 16a increases when heating and pressing progress as illustrated in FIG. 18, excessive pressing force is applied, or a tilt is given to the radiator 170 or the substrate 11. As a result of such a phenomenon, as illustrated in FIGS. 13D and 14, the heat conducting material 16 (outflow portion 16b) which flows out flows toward the substrate 11. By doing so, the outflow portion 16b adheres to an electronic component 13 mounted around the semiconductor element 12 or the substrate 11 (wiring, a pad, or the like formed on the surface). This causes an electric trouble.

Even if assembly is performed by placing the substrate 11 over which the semiconductor element 12 and the electronic components 13 are mounted on an upper side, placing the radiator 170 on a lower side, and placing the heat conducting material 16 between them, an electric trouble may occur. The reason for this is that as a result of heating and pressing, the heat conducting material 16 flows out, bursts, and scatters.

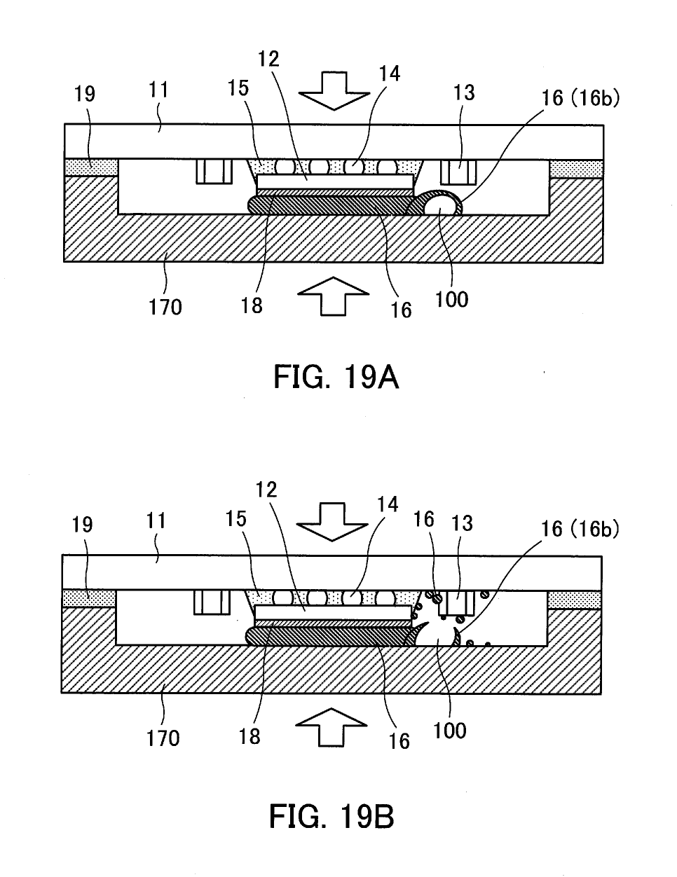

FIGS. 19A and 19B are schematic sectional views of an example of an assembly step.

In FIGS. 19A and 19B, heating and pressing are performed with the substrate 11 and the radiator 170 placed on upper and lower sides respectively. Even in this case, an oxide film formed on the surface of the heat conducting material 16 ruptures and the internal heat conducting material 16 flows out through a rupture. This is the same with the above case. As illustrated in FIG. 19A, for example, air 100 may be contained in the outflow portion 16b of the heat conducting material 16 or in the process of the outflow of the heat conducting material 16 the air 100 may be taken in. In this case, the air 100 expands by heating and shrinks by pressing. As a result, as illustrated in FIG. 19B, the outflow portion 16b may burst and the heat conducting material 16 may scatter about. The heat conducting material 16 which scatters may adhere not only to a side of the semiconductor element 12 or the surface (fillet portion) of an under-fill resin 15 near the outflow portion 16b but also to an electronic component 13 or the substrate 11. An electric trouble, such as a short circuit, may occur depending on a place to which the heat conducting material 16 adheres after scattering or an amount by which the heat conducting material 16 adheres after scattering.

The electronic components 13, such as chip capacitors, mounted around the semiconductor element 12 are electrically connected to the semiconductor element 12 by wirings (not illustrated) in the substrate 11. In order to control the inductance of the wirings which produces switching noise, it is desirable to arrange the electronic components 13 near the semiconductor element 12.

However, if the above radiator 170 having no projections is used and the electronic components 13 are arranged near the semiconductor element 12, the heat conducting material 16 which flows out as a result of heating and pressing at assembly time is apt to adhere to an electronic component 13. Accordingly, an electric trouble, such as a short circuit, is apt to occur. In order to prevent the heat conducting material 16 which flows out from adhering to an electronic component 13, a design and a structure in which the electronic components 13 are arranged farther from the semiconductor element 12 may be adopted. In this case, however, an inductance increases between the semiconductor element 12 and an electronic component 13 and the influence of switching noise grows. Furthermore, if such a design or a structure is adopted, a space for the electronic components 13 may be limited or the size of a semiconductor device may increase.

In addition, there is a form of a semiconductor device in which the above under-fill resin 15 is not used.

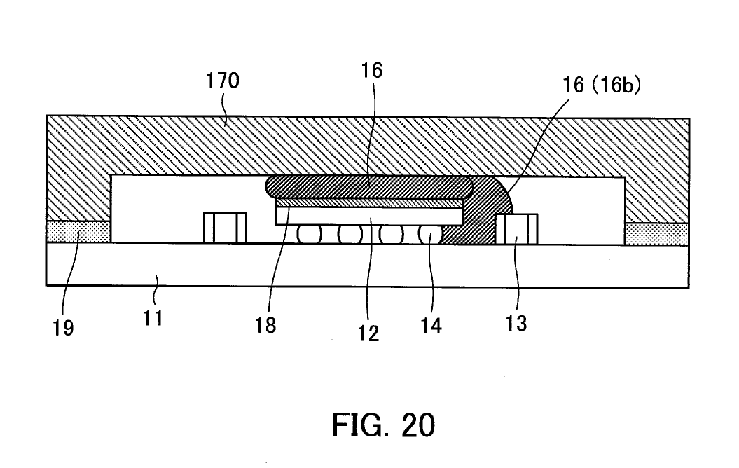

FIG. 20 is a schematic sectional view of a semiconductor device having still another structure.

As illustrated in FIG. 20, a semiconductor device in which an under-fill resin 15 is not used and in which a semiconductor element 12 and a substrate 11 are connected only by bumps 14 can be assembled. However, if a radiator 170 having no projections is used in such a semiconductor device, a heat conducting material 16 (outflow portion 16b) which flows out at, for example, assembly time may flow to the under side of the semiconductor element 12 and touch a bump 14. As a result, a short circuit occurs.

The outflow of heat conducting material 16 illustrated in FIG. 13D, 14, 19A, 19B, or 20 and a short circuit thereby caused may occur not only at the time of assembling a semiconductor device but also at the time of mounting a semiconductor device after assembly over another board, such as a mother board. For example, solder balls are mounted over the substrate 11 of the semiconductor device, the solder balls are melted by heating (reflowed), and the semiconductor device is mounted over a mother board. If not only the solder balls but also the heat conducting material 16 melts at reflow time, the above outflow may occur. If the semiconductor device is tilted or joggled at the time of mounting it over the mother board, then the heat conducting material 16 is more apt to flow out.

Furthermore, in the above description a conductive material, such as solder, is used as the heat conducting material 16 and an electric trouble may be caused by the melting and overflow of the conductive heat conducting material 16. In addition, a nonconductive material, such as resin, can be used as the heat conducting material 16. Even if such a material is used, an electric trouble may be caused by its outflow.

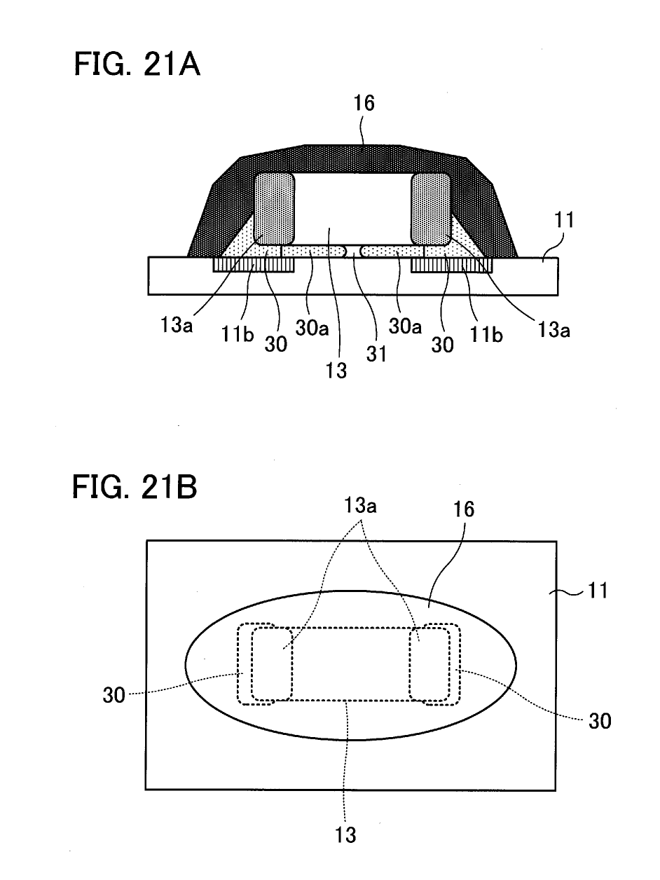

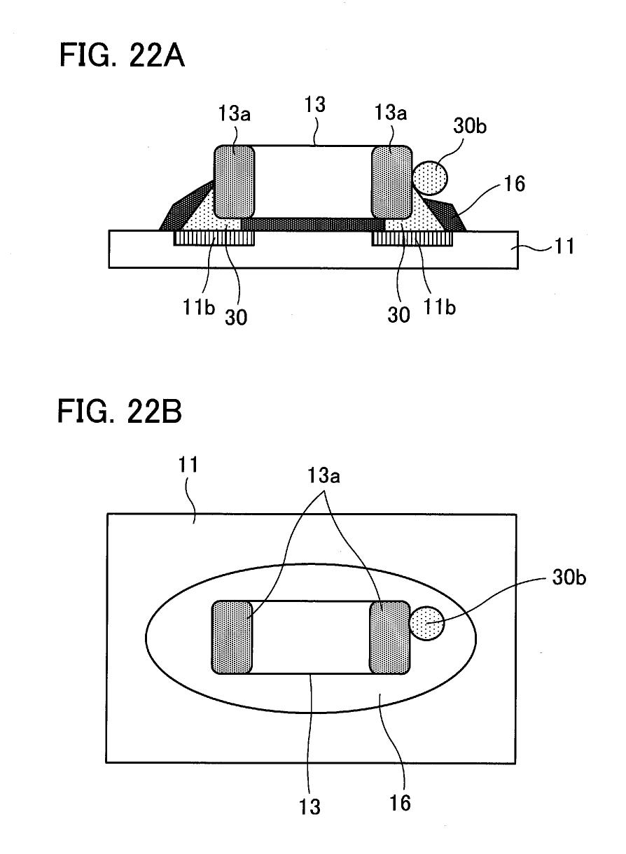

FIGS. 21A and 21B and FIGS. 22A and 22B are views for describing a case in which a nonconductive material is used as a heat conducting material. FIGS. 21A and 22A are schematic sectional views and FIGS. 21B and 22B are schematic plan views.

A resin material, such as under-fill resin, can be used as a heat conducting material 16. Even in this case, a semiconductor device can be assembled in accordance with, for example, the above flow illustrated in FIGS. 13A through 13C, and the heat conducting material 16, which is resin, is heated and pressed. When the heat conducting material 16, which is resin, is heated and pressed, the heat conducting material 16 which is not yet hardened may be extruded by pressing and flow out from over a semiconductor element 12. This is the same with, for example, FIG. 13D.

As illustrated in FIGS. 21A and 21B, for example, the heat conducting material 16 which is resin and which flows out from over the semiconductor element 12 may cover an entire electronic component 13 bonded to (mounted on) electrode pads 11b of a substrate 11 with a bonding member 30, such as solder, and be hardened in that state. When the electronic component 13 is covered with the heat conducting material 16, which is resin, in this way, there appears what is called an airtight void 31 between the electronic component 13 and the substrate 11. In such a case, the bonding member 30, which is solder, may melt as a result of heating and flow into the void 31, in a later heating step (step of mounting the semiconductor device over a mother board, for example). When the bonding member 30 (outflow portion 30a) which flows out from the one electrode pad 11b side touches the bonding member 30 (outflow portion 30a) which flows out from the other electrode pad 11b side, the other electrode pad 11b, the bonding member 30 connected to the other electrode pad 11b, or an electrode 13a of the electronic component 13, a short circuit occurs.

Furthermore, as illustrated in FIGS. 22A and 22B, the heat conducting material 16 which is resin and which flows out from over the semiconductor element 12 may cover the bonding member 30 with a part of it exposed, and be hardened in that state. In such a case, the bonding member 30, which is solder, may melt as a result of heating and flow out from the part not covered with the heat conducting material 16, in a later heating step. If the bonding member 30 (outflow portion 30b) flows out in this way, the amount of the bonding member 30 which connects the electrode pad lib of the substrate 11 and the electrode 13a of the electronic component 13 decreases and the reliability of connection may deteriorate. In addition, the bonding member 30 (outflow portion 30b) which flows out may drop or scatter and touch another electronic component 13 or the substrate 11. As a result, an electric trouble may occur.

With the semiconductor device in which the radiator 170 having no projections is used, as has been described, the heat conducting material 16 may flow out from over the semiconductor element 12 at assembly time or after assembly. An electric trouble, such as a short circuit, may be caused by the heat conducting material 16 which flows out.

With the semiconductor device 10A according to the above first embodiment, on the other hand, the radiator 17 on which the projections 17b are formed is used. Accordingly, it is possible to make the heat conducting material 16 which flows out at assembly time or after assembly touch a projection 17b, adhere to the radiator 17, and spread along the radiator 17. As a result, adhesion of the heat conducting material 16 which flows out to an electronic component 13 or the substrate 11 or an electric trouble, such as a short circuit, caused by such adhesion is effectively prevented. In addition, after the heat conducting material 16 begins to flow out, it touches the projection 17b in a comparatively early stage and adheres to and spreads along the radiator 17. Therefore, an outflow portion of the heat conducting material 16 is unapt to take air in. In addition, scattering about of the heat conducting material 16 caused by a burst of the outflow portion is effectively prevented.

As has been described, with the semiconductor device 10A adhesion of the heat conducting material 16 which flows out to an electronic component 13 or the substrate 11 can be prevented, so the electronic components 13 can be arranged near the semiconductor element 12. As a result, an inductance can be reduced between the semiconductor element 12 and an electronic component 13 and switching noise can be reduced.

The projections 17b of various shapes can be formed on the radiator 17 of the semiconductor device 10A.

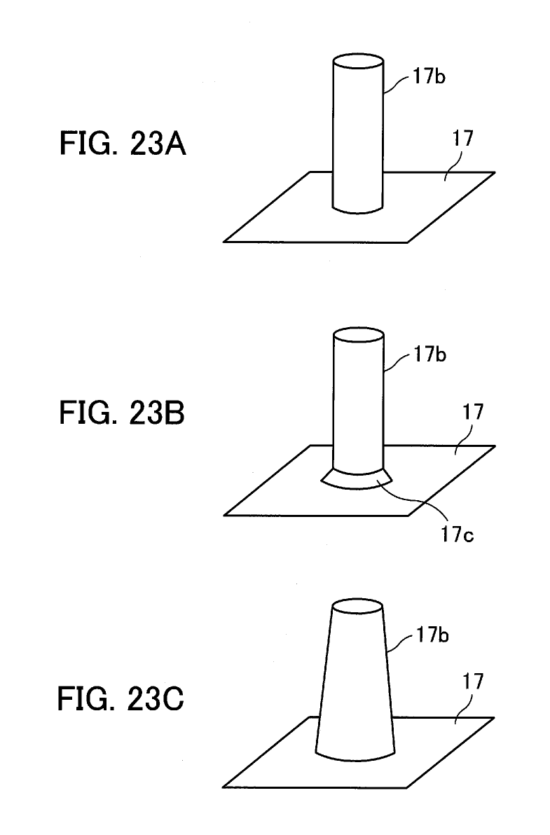

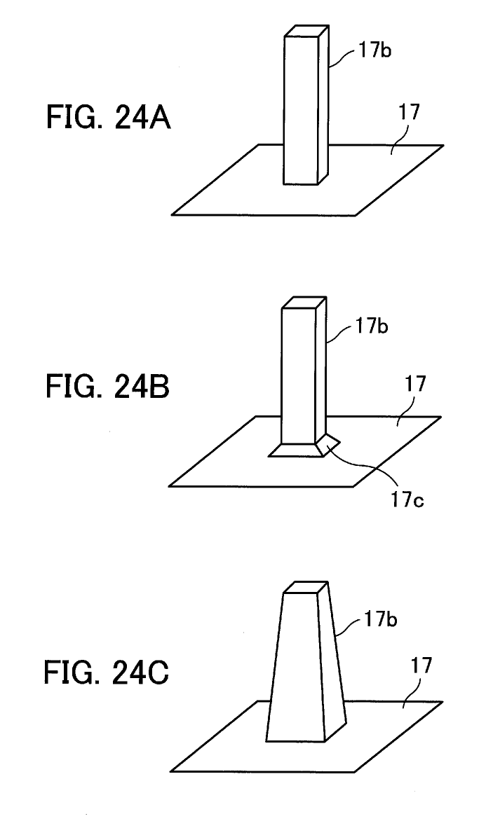

FIGS. 23A through 23C and FIGS. 24A through 24C are examples of the shape of the projections formed on the radiator.

As illustrated in FIG. 23A, the projections 17b each having a cylindrical shape can be formed on the radiator 17. Furthermore, as illustrated in FIG. 23B, each projection 17b in the shape of a cylinder a root portion 17c of which has a taper shape can be formed on the radiator 17. In addition, as illustrated in FIG. 23C, the projections 17b each having the shape of a circular truncated cone can be formed on the radiator 17. Forming each projection 17b in the shape of a cylinder the root portion 17c of which has a taper shape or forming each projection 17b having the shape of a circular truncated cone makes it possible to effectively prevent air from being taken in between the heat conducting material 16 which flows and the projections 17b.

In addition, as illustrated in FIG. 24A, the projections 17b each having the shape of a quadrangular prism can be formed. Furthermore, from the viewpoint of more effectively preventing air from being taken in, each projection 17b in the shape of a quadrangular prism with a root portion 17c having a taper shape can be formed as illustrated in FIG. 24B, or each projection 17b having the shape of a prismoid can be formed as illustrated in FIG. 24C.

The radiator 17 can be formed by press working, molding, or the like according to its material. The projections 17b, together with the concave portion 17a, can be formed at press working time or molding time. Furthermore, the radiator 17 having only the concave portion 17a of the concave portion 17a and the projections 17b is formed by press working, molding, or the like and the projections 17b formed separately from the concave portion 17a by press working, molding, or the like may be connected to the formed concave portion 17a by a proper method such as adhesion, bonding, or welding.

There is no special limitation on the height of the projections 17b, except that at the time of assembling the semiconductor device 10A (and after the assembly of the semiconductor device 10A), the projections 17b do not interfere with the electronic components 13 arranged in a direction in which they protrude or the substrate 11 and that at the time of assembling the semiconductor device 10A (and after the assembly of the semiconductor device 10A), the projections 17b can make the heat conducting material 16 which flows out adhere to and spread among them. In the fabricated semiconductor device 10A the height of the projections 17b can be set by finding a proper value in advance by experiment or the like. For example, the height of the projections 17b can be set on the basis of the height of the mounted electronic components 13 arranged in the direction in which the projections 17b protrude, the distance to the substrate 11, and the like.

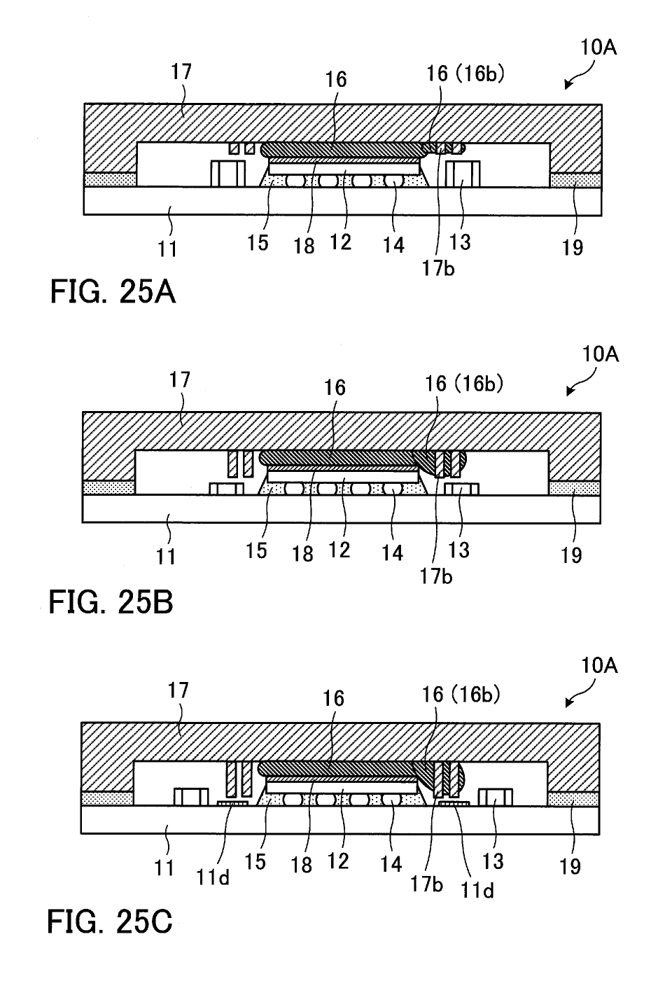

FIGS. 25A, 25B, and 25C are examples of a semiconductor device which differ in the height of projections on a radiator.

As illustrated in FIG. 25A, if the height of mounted electronic components 13 arranged near a semiconductor element 12 in a direction in which projections 17b protrude is relatively great, then the height of the projections 17b is set to a relatively small value so that the projections 17b will not interfere with the electronic components 13 and so that the projections 17b can make a heat conducting material 16 which flows out adhere to and spread among them. As illustrated in FIG. 25B, if the height of mounted electronic components 13 arranged near a semiconductor element 12 in a direction in which projections 17b protrude is relatively small, then the height of the projections 17b is set to a relatively great value so that the projections 17b will not interfere with the electronic components 13 and so that the projections 17b can make a heat conducting material 16 which flows out adhere to and spread among them. Furthermore, as illustrated in FIG. 25C, if electronic components 13 are not arranged in regions opposite to projections 17b, then the height of the projections 17b is set to a relatively great value so that the projections 17b will not interfere with a substrate 11 (conductive portions 11b, such as wirings and pads, formed on the surface) and so that the projections 17b can make a heat conducting material 16 which flows out adhere to and spread among them.

In the above semiconductor device 10A according to the first embodiment the number and arrangement of the projections 17b on the radiator 17 are examples. If it is possible to make the heat conducting material 16 which flows out adhere to and spread among the projections 17b, then the number and arrangement of the projections 17b are not limited to the above examples.

A second embodiment will now be described.

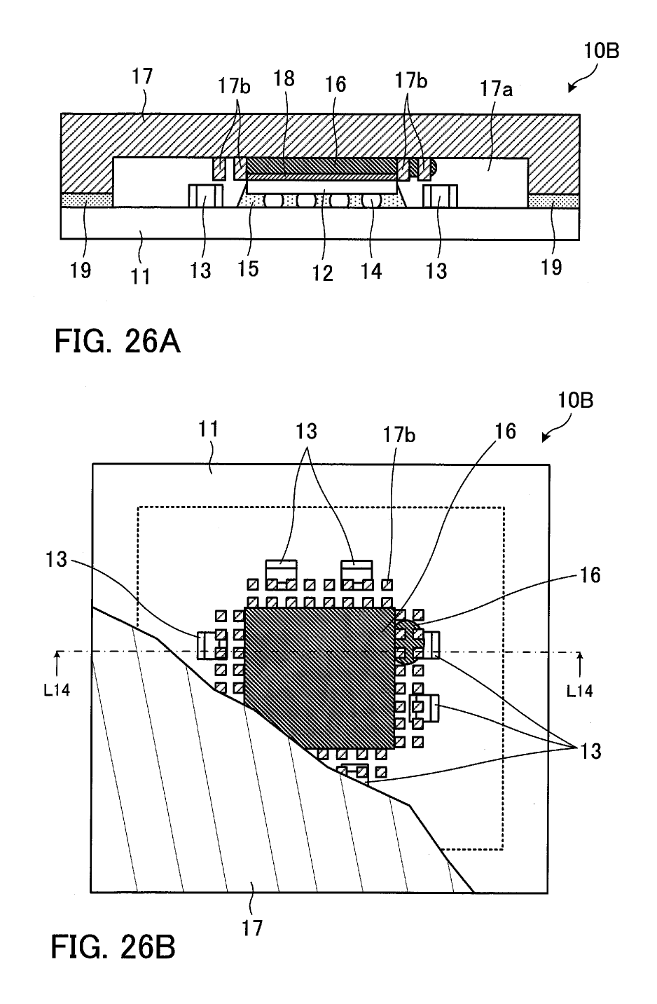

FIGS. 26A and 26B are an example of a semiconductor device according to a second embodiment. FIG. 26B is a schematic plan view of an example of a semiconductor device according to a second embodiment. FIG. 26A is a schematic sectional view taken along lines L14-L14 of FIG. 26B.

With a semiconductor device 10B according to a second embodiment projections 17b on a radiator 17 are formed nearer a semiconductor element 12 (so that the projections 17b will be touching sides of the semiconductor element 12, in this example). In this respect the semiconductor device 10B according to the second embodiment and the above semiconductor device 10A according to the first embodiment differ.

By forming the projections 17b nearer the semiconductor element 12, a heat conducting material 16 which flows out is apt to touch a projection 17b in an earlier stage. For example, it is possible to make the heat conducting material 16 touch a projection 17b at the time when it begins to flow out. By making it easy in this way for the heat conducting material 16 to touch a projection 17b, adhesion of the heat conducting material 16 which flows out to an electronic component 13 or the substrate 11 or an electric trouble caused by such adhesion can effectively be prevented.

The arrangement of the projections 17b in the semiconductor device 10B has the following advantage in its assembly.

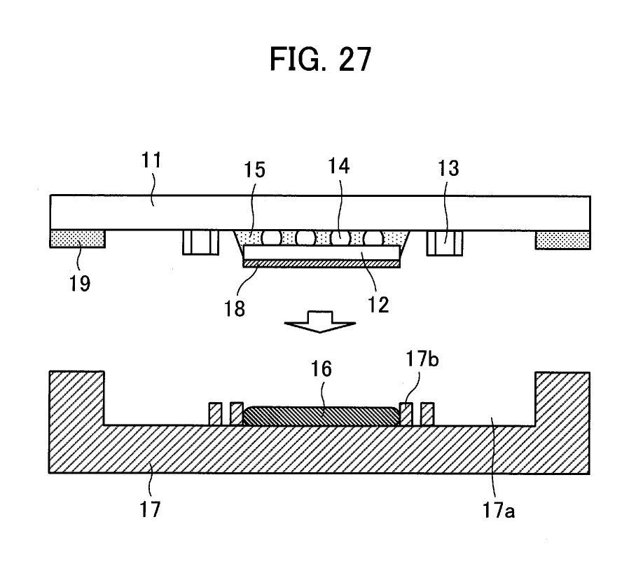

FIG. 27 is a schematic sectional view of an example of the step of assembling the semiconductor device according to the second embodiment.

As illustrated in FIG. 27, for example, the heat conducting material 16 is placed inside a region in which the projections 17b are formed over the radiator 17 placed with a concave portion 17a and the projections 17b upward when the semiconductor device 10B is assembled. The substrate 11 over which the semiconductor element 12 and electronic components 13 are mounted and over which an adhesive 19 is placed is placed over the radiator 17 over which the heat conducting material 16 is placed in this way. At the same time that heating is being performed at a determined temperature, each of the substrate 11 and the radiator 17 is then pressed toward the other.

The projections 17b are arranged so that they will be close to the semiconductor element 12 after assembly. Accordingly, in this assembly the heat conducting material 16 placed inside the region in which the projections 17b are formed is aligned with the semiconductor element 12 with accuracy. This makes it possible to bond the heat conducting material 16 and the semiconductor element 12 together with deviation between their positions small.

If the semiconductor device in which the radiator 170 having no projections 17b is used is assembled, deviation between the positions of the heat conducting material 16 and the semiconductor element 12 is comparatively apt to occur. If the heat conducting material 16 and the semiconductor element 12 are bonded together in a state in which there is deviation between their positions, a region not covered with the heat conducting material 16 appears on the upper side of the semiconductor element 12 and heat transferability from the semiconductor element 12 at operation time to the radiator 170 may deteriorate (thermal resistance may increase). As a result, the semiconductor element 12 overheats and a malfunction may occur in the semiconductor element 12. In addition, a yield in semiconductor device assembly drops.

By using the radiator 17 on which the projections 17b are arranged in the above way so as to be close to the semiconductor element 12 after assembly, on the other hand, the projections 17b function as a guide for the heat conducting material 16 and deviation between the positions of the heat conducting material 16 and the semiconductor element 12 at assembly time can be reduced. Accordingly, the heat conducting material 16 can be boded to the entire upper side of the semiconductor element 12 with accuracy and a deterioration in heat transferability from the semiconductor element 12 to the radiator 17 can effectively be controlled.

A third embodiment will now be described.

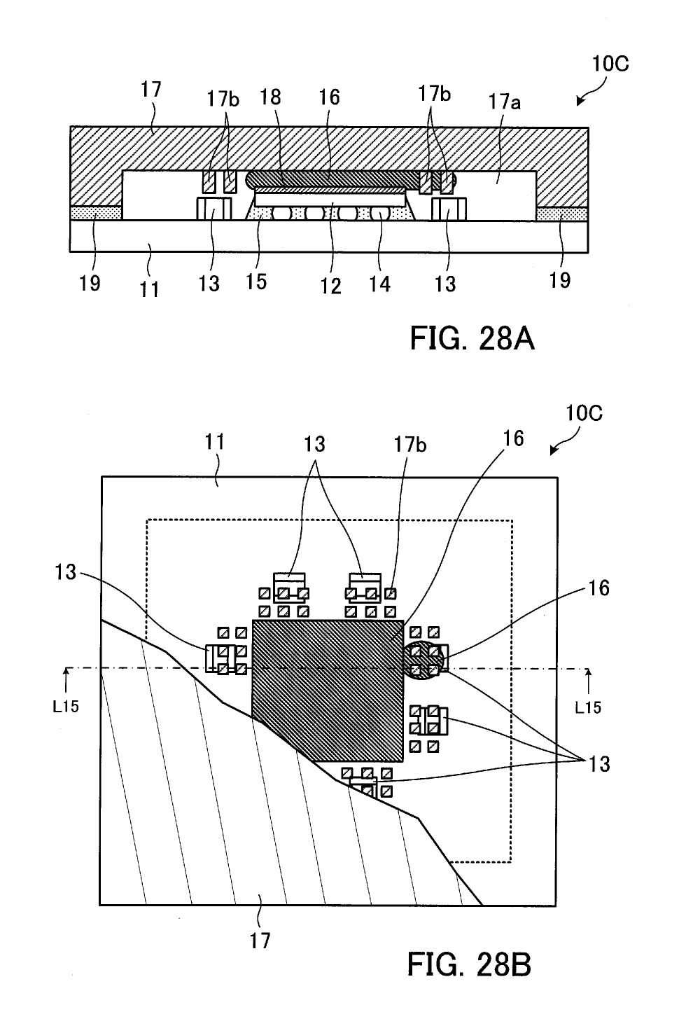

FIGS. 28A and 28B are an example of a semiconductor device according to a third embodiment. FIG. 28B is a schematic plan view of an example of a semiconductor device according to a third embodiment. FIG. 28A is a schematic sectional view taken along lines L15-L15 of FIG. 28B.

With a semiconductor device 100 according to a third embodiment projections 17b on a radiator 17 are selectively formed in regions opposite to electronic components 13. In this respect the semiconductor device 100 according to the third embodiment and the above semiconductor device 10A according to the first embodiment differ. In a word, with the semiconductor device 100 according to the third embodiment a part of the projections 17b in the above semiconductor device 10A according to the first embodiment are removed.

Even if a heat conducting material 16 flows out in the semiconductor device 100, it is possible to make the heat conducting material 16 adhere to and spread among projections 17b selectively formed in regions opposite to electronic components 13. As a result, adhesion of the heat conducting material 16 which flows out to the electronic components 13 or the like or an electric trouble caused by such adhesion can effectively be prevented.

In addition, with the semiconductor device 10C the projections 17b are selectively formed according to the arrangement of the electronic components 13 (part of the projections 17b in the above semiconductor device 10A according to the first embodiment are removed), so an excessive overflow of the heat conducting material 16 into the regions in which the projections 17b are formed can be prevented.

That is to say, the heat conducting material 16 which flows out from over a semiconductor element 12 adheres to and spreads in a region in which projections 17b are formed by capillarity. If an excessive overflow of the heat conducting material 16 occurs in this way, then the amount of the heat conducting material 16 which remains over the semiconductor element 12 may decrease. If the amount of the heat conducting material 16 over the semiconductor element 12 decreases, then heat transferability between the semiconductor element 12 and a radiator 17 may deteriorate (thermal resistance may increase) and the semiconductor element 12 may overheat. With the semiconductor device 100 the projections 17b are selectively formed in the above way according to the arrangement of the electronic components 13. By doing so, such an excessive overflow of the heat conducting material 16 is prevented.

Furthermore, by selectively forming the projections 17b in this way according to the arrangement of the electronic components 13, the number of the projections 17b can be decreased and a material cost and manufacturing costs for the radiator 17 can be reduced. In addition, the radiator 17 and the semiconductor device 100 using it can be lightened.

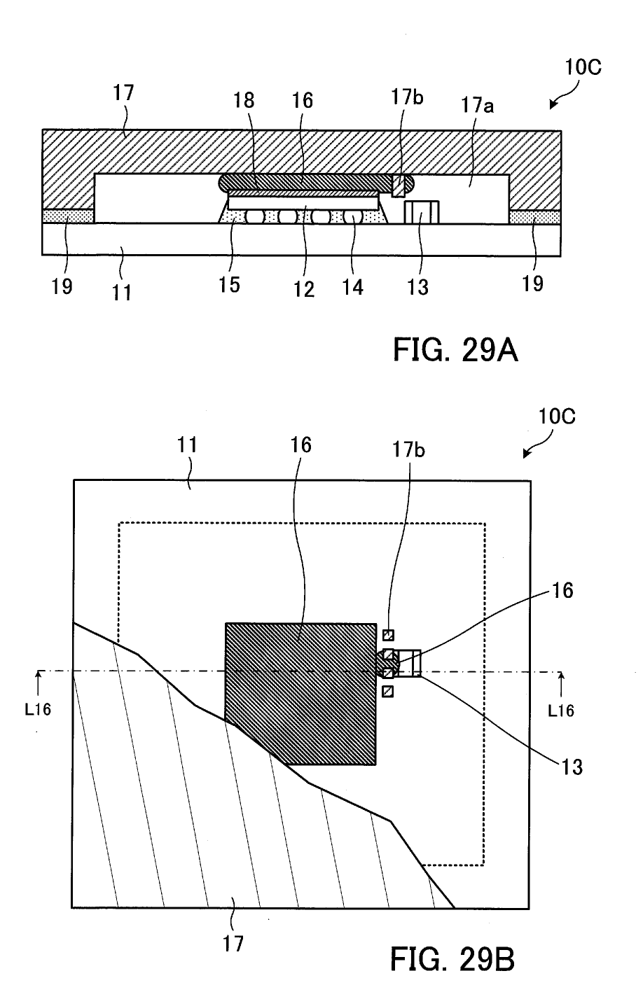

FIGS. 29A and 29B are another example of the semiconductor device according to the third embodiment. FIG. 29B is a schematic plan view of another example of the semiconductor device according to the third embodiment. FIG. 29A is a schematic sectional view taken along lines L16-L16 of FIG. 29B.

As illustrated in FIGS. 29A and 29B, if the number of electronic components 13 is small (one, in this example), then projections 17b may selectively be formed in a region corresponding to the electronic component 13. Even if the projections 17b are formed in this way, adhesion of a heat conducting material 16 which flows out to the electronic component 13 or the like can be prevented. Furthermore, if the projections 17b are formed in this way, a material cost and manufacturing costs for a radiator 17 can be reduced. In addition, the radiator 17 and the semiconductor device 100 using it can be lightened.

The projections 17b selectively formed in the semiconductor device 100 according to the arrangement of the electronic components 13 may be formed so as to be close to the semiconductor element 12. This is the same with the above second embodiment. By doing so, the same effect that is described in the above second embodiment can be obtained.

A fourth embodiment will now be described.

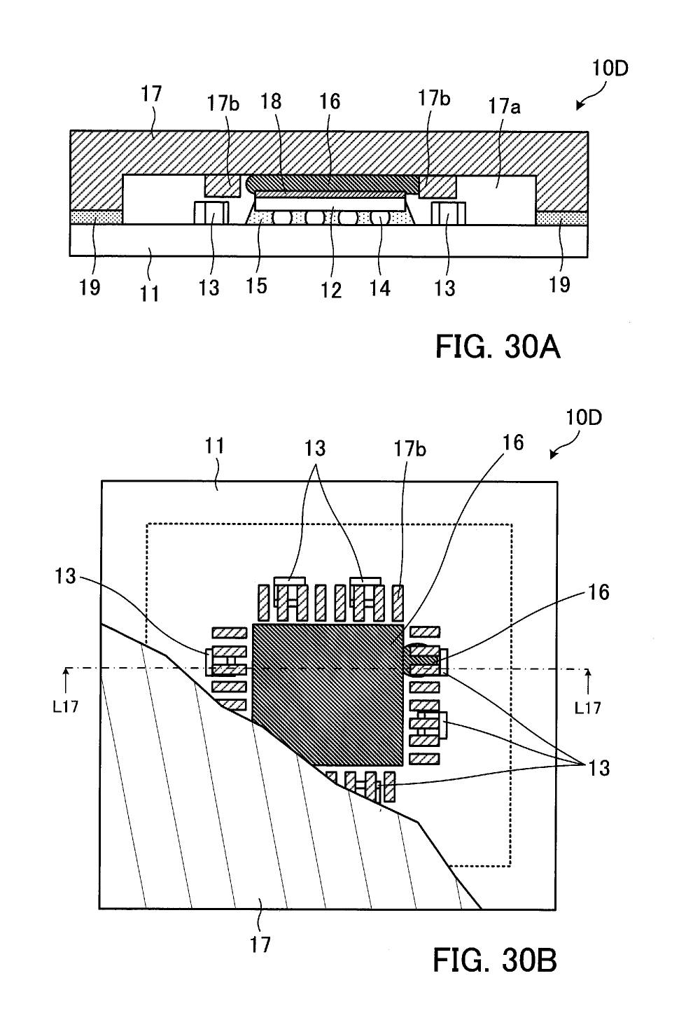

FIGS. 30A and 30B are an example of a semiconductor device according to a fourth embodiment. FIG. 30B is a schematic plan view of an example of a semiconductor device according to a fourth embodiment. FIG. 30A is a schematic sectional view taken along lines L17-L17 of FIG. 30B.

With a semiconductor device 10D according to a fourth embodiment projections 17b on a radiator 17 are formed so as to extend outward from a semiconductor element 12 side. In this respect the semiconductor device 10D according to the fourth embodiment and the above semiconductor device 10A according to the first embodiment differ.

FIGS. 30A and 30B illustrate the semiconductor device 10D in which the plate-like projections 17b are formed so as to extend outward from the semiconductor element 12 side. In the semiconductor device 10D a heat conducting material 16 which flows out from over the semiconductor element 12 touches a plate-like projection 17b and adheres to and spreads among plate-like projections 17b by capillarity.

The surface area of the projections 17b in the semiconductor device 10D is small compared with a case where the above pin-like projections are formed. Accordingly, an excessive overflow of the heat conducting material 16 from over the semiconductor element 12 can be prevented. As a result, a deterioration in heat transferability between the semiconductor element 12 and the radiator 17 (increase in thermal resistance) or the overheating of the semiconductor element 12 caused by it can be prevented.

The projections 17b formed in the semiconductor device 10D so as to extend outward from the semiconductor element 12 side may be formed so as to be close to the semiconductor element 12. This is the same with the above second embodiment. By doing so, the same effect that is described in the above second embodiment can be obtained.

Furthermore, if the number of electronic components 13 is small, then the projections 17b may selectively be formed in regions corresponding to the electronic components 13 so as to extend outward from the semiconductor element 12 side. This is the same with FIGS. 29A and 29B.

The first through fourth embodiments have been described. It is possible to combine the arrangements or structures of the projections 17b described in these embodiments.

A fifth embodiment will now be described,

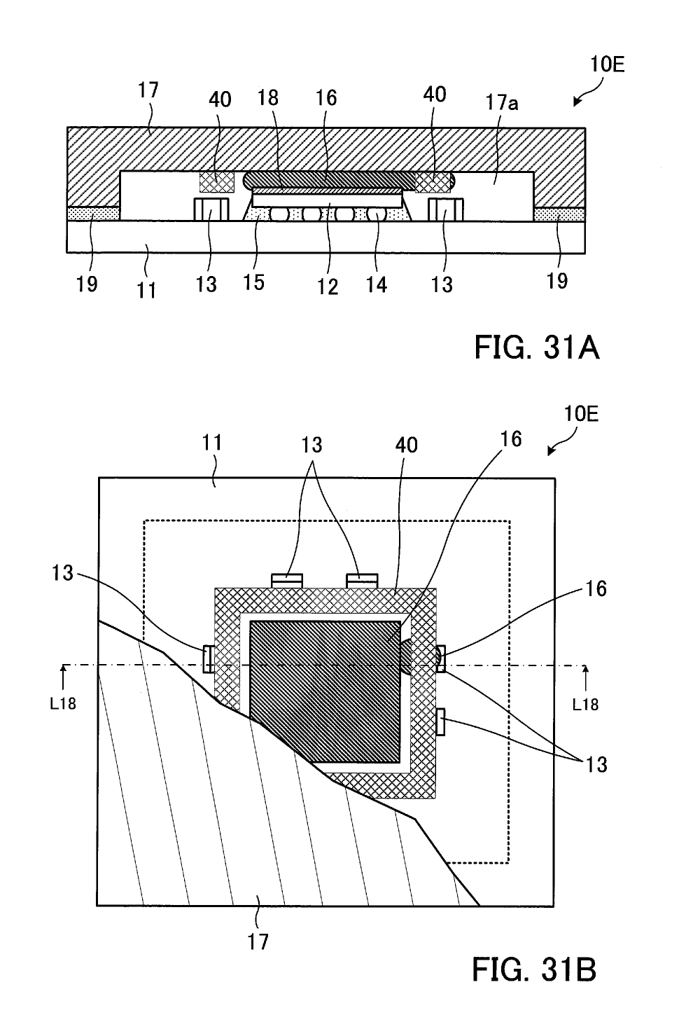

FIGS. 31A and 31B are an example of a semiconductor device according to a fifth embodiment. FIG. 31B is a schematic plan view of an example of a semiconductor device according to a fifth embodiment. FIG. 31A is a schematic sectional view taken along lines L18-L18 of FIG. 31B.

With a semiconductor device 10E according to a fifth embodiment a net-like wire member 40 is formed in place of projections 17b in a region of a radiator 17 outside a region opposite to a semiconductor element 12. In this respect the semiconductor device 10E according to the fifth embodiment and the above semiconductor device 10A according to the first embodiment differ.

Metal thin wires of Cu or the like which are braided can be used as the net-like wire member 40. For example, a solder absorbing wire can be used as the wire member 40. By forming the wire member 40 on the radiator 17 having a concave portion 17a, it is possible to make a heat conducting material 16 which flows out from over the semiconductor element 12 adhere to and spread along the wire member 40. This is the same with a case where the above projections 17b are formed. As a result, adhesion of the heat conducting material 16 which flows out to an electronic component 13 or the like or an electric trouble caused by such adhesion can effectively be prevented.

A method for assembling the semiconductor device 10E using the wire member 40 will now be described.

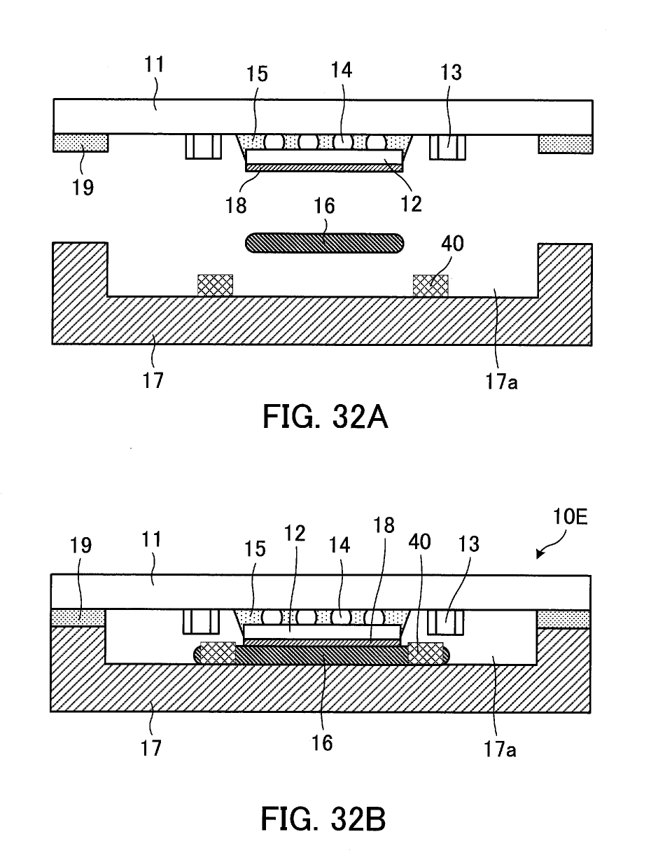

FIGS. 32A and 32B are schematic sectional views of an example of the step of assembling the semiconductor device according to the fifth embodiment.

As illustrated in FIG. 32A, for example, the wire member 40 is placed over the radiator 17 placed with the concave portion 17a upward when the semiconductor device 10E is assembled. At this point of time it is not necessary to fix the wire member 40 to the radiator 17. For example, the wire member 40 may be put over the radiator 17 or temporarily be connected to the radiator 17.

In addition to placing the wire member 40 over the radiator 17, the heat conducting material 16 is placed over the radiator 17 so that it will be placed inside the wire member 40. A substrate 11 over which the semiconductor element 12 and electronic components 13 are mounted and over which an adhesive 19 is placed is placed over the radiator 17 over which the wire member 40 and the heat conducting material 16 are placed in this way. At the same time that heating is being performed at a determined temperature, each of the substrate 11 and the radiator 17 is then pressed toward the other.

As illustrated in FIG. 32B, the heat conducting material 16 which flows out at the time of the heating and the pressing adheres to and spreads along the wire member 40. This makes it possible to prevent the heat conducting material 16 which flows out from adhering to an electronic component 13 or the like. Furthermore, when the heat conducting material 16 which adheres to and spreads along the wire member 40 solidifies, the wire member 40 is bonded to the radiator 17 by the heat conducting material 16 which solidifies. Therefore, it is not necessary to fix the wire member 40 in advance to the radiator 17. This makes it possible to reduce costs and man-hours necessary for making the radiator 17.

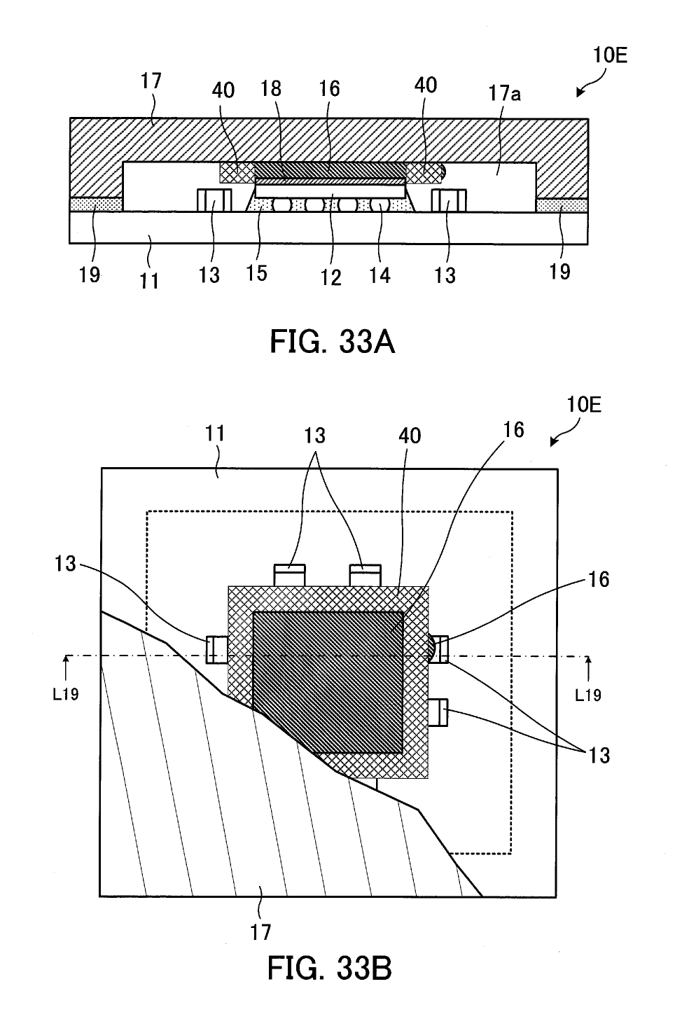

FIGS. 33A and 33B are another example of the semiconductor device according to the fifth embodiment. FIG. 33B is a schematic plan view of another example of the semiconductor device according to the fifth embodiment. FIG. 33A is a schematic sectional view taken along lines L19-L19 of FIG. 33B.

In the semiconductor device 10E using the above net-like wire member 40, the wire member 40 can be formed so as to be close to the semiconductor element 12. This is the same with the above second embodiment. By doing so, the heat conducting material 16 which flows out touches the wire member 40 in an early stage. As a result, an electric trouble caused by the heat conducting material 16 which flows out can effectively be prevented. This is the same with the above second embodiment.

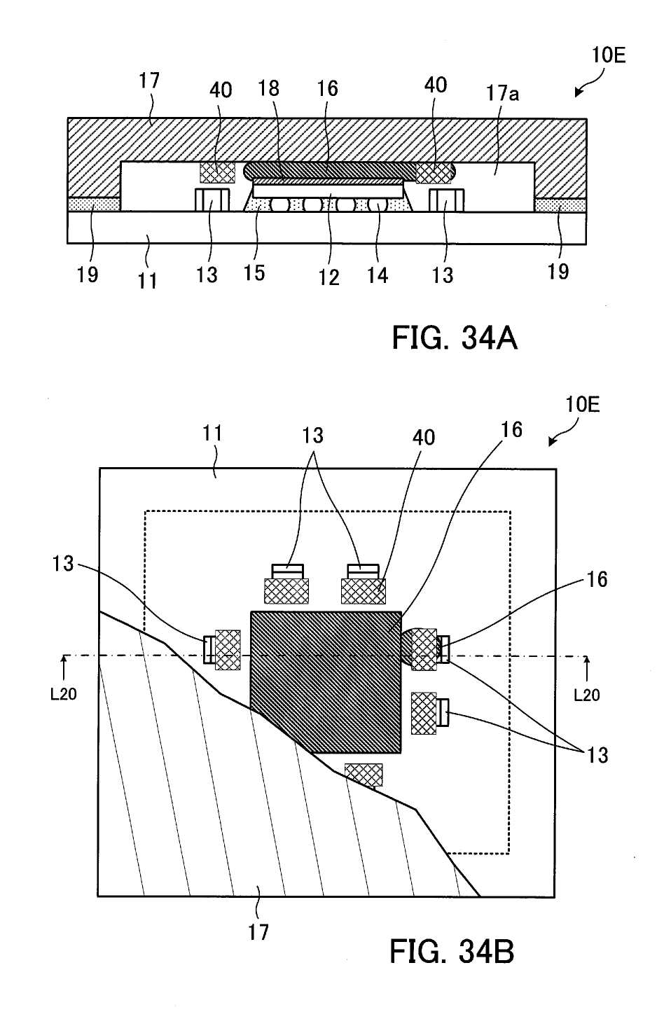

FIGS. 34A and 34B are another example of the semiconductor device according to the fifth embodiment. FIG. 34B is a schematic plan view of another example of the semiconductor device according to the fifth embodiment. FIG. 34A is a schematic sectional view taken along lines L20-L20 of FIG. 34B.

In the semiconductor device 10E using the above net-like wire member 40, the wire member 40 can selectively be formed in regions opposite to the electronic components 13. This is the same with the above third embodiment. By doing so, an excessive overflow of the heat conducting material 16 (excessive blotting of the heat conducting material 16 by the wire member 40) can be prevented. This is the same with the above third embodiment. As a result, a deterioration in heat transferability between the semiconductor element 12 and the radiator 17 (increase in thermal resistance) or the overheating of the semiconductor element 12 caused by it can be prevented.

The net-like wire member 40 described in the fifth embodiment can be used in place of a part of the projections 17b described in the above first, second, third, or fourth embodiment.

A sixth embodiment will now be described.

In the above description the semiconductor devices 10A through 10E each using the radiator 17 having the concave portion 17a are taken as examples. However, a semiconductor device can be fabricated by using a plate-like radiator which does not have the above concave portion 17a and on which the above projections 17b or net-like wire member 40 is formed.

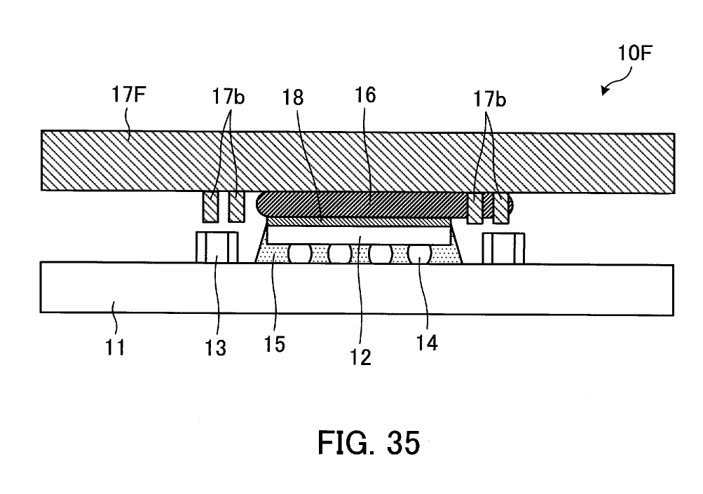

FIG. 35 is an example of a semiconductor device using a plate-like radiator. FIG. 35 is a schematic sectional view of a semiconductor device using a plate-like radiator.

A semiconductor device 10F illustrated in FIG. 35 has a structure in which a plate-like radiator 17F is used in place of the radiator 17 of the semiconductor device 10A according to the above first embodiment having the concave portion 17a. Like the above radiator 17, the plate-like radiator 17F has a plurality of projections 17b outside a region opposite to a semiconductor element 12. The plate-like radiator 17F is bonded to the semiconductor element 12 (bonding layer 18) over a substrate 11 by a heat conducting material 16. With the semiconductor device 10F an adhesive 19 is unnecessary. The costs of making the plate-like radiator 17F can be made low, compared with the above radiator 17 having the concave portion 17a. However, even if the plate-like radiator 17F illustrated in FIG. 35 is used, the heat conducting material 16 which flows out at assembly time or after assembly from over the semiconductor element 12 adheres to and spreads among projections 17b. As a result, an outflow of the heat conducting material 16 toward the substrate 11 or adhesion of the heat conducting material 16 to the substrate 11 or an electronic component 13 caused by it is prevented. Accordingly, the semiconductor device 10F in which an electric trouble caused by adhesion of the heat conducting material 16 which flows out is prevented can be obtained.

A case where the plate-like radiator 17F is used in place of the radiator 17 of the semiconductor device 10A according to the above first embodiment has been taken as an example. However, it is possible to use the plate-like radiator 17F in place of the radiator 17 included in each of the semiconductor devices 10B through 10E according to the above second through fifth embodiments respectively. Even in such a case, the same effect that is described above can be obtained.

As has been described in the foregoing, in a semiconductor device in which a semiconductor element and a radiator are thermally connected with a heat conducting material between, a plurality of projections or a net-like wire member is farmed in a region of the radiator outside a region opposite to the semiconductor element. This makes it possible to make the heat conducting material which flows out from over the semiconductor element at the time of or after assembling the semiconductor device touch a projection or the net-like wire member and adhere to and spread in the region in which the projections or the net-like wire member is formed. As a result, adhesion of the heat conducting material which flows out from over the semiconductor element to a substrate over which the semiconductor element is mounted or an electronic component which, together with the semiconductor element, is mounted over the substrate can be prevented or an electric trouble caused by such adhesion can effectively be prevented. Therefore, a high-quality high performance semiconductor device in which an electric trouble caused by the outflow and scattering of the heat conducting material is prevented is realized.

According to the disclosed techniques a high-quality high performance semiconductor device in which the outflow and scattering of a heat conducting material are prevented by a plurality of projections or a net-like wire member on a radiator and in which an electric trouble caused by the outflow and scattering of the heat conducting material is prevented can be realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a substrate;
a semiconductor element placed over the substrate;
a heat conducting material placed over the semiconductor element; and
a radiator placed over the heat conducting material,
the radiator having a plurality of projections which are arranged outside a region opposite to the semiconductor element and which protrude toward the substrate.

2. The semiconductor device according to claim 1, wherein the plurality of projections are arranged along a circumference of the region opposite to the semiconductor element.

3. The semiconductor device according to claim 1 further comprising electronic components arranged outside the semiconductor element over the substrate, wherein the plurality of projections are selectively arranged over the electronic components so as not to touch the electronic components.

4. The semiconductor device according to claim 1 further comprising electronic components arranged outside the semiconductor element over the substrate, wherein the plurality of projections are arranged between the semiconductor element and the electronic components so as not to touch the substrate.

5. The semiconductor device according to claim 1, wherein positions of projections of the plurality of projections at ends on a semiconductor element side correspond to positions of ends of the semiconductor element.

6. The semiconductor device according to claim 1, wherein the plurality of projections include projections which extend outward from the semiconductor element.

7. The semiconductor device according to claim 1, wherein the heat conducting material is placed between the semiconductor element and the region opposite to the semiconductor element and among the plurality of projections.

8. A method for fabricating a semiconductor device, the method comprising:
placing a semiconductor element over a substrate;
placing a radiator over a surface of the substrate over which the semiconductor element is placed with a heat conducting material placed between the semiconductor element and the radiator; and
pressing the radiator toward the substrate and heating the heat conducting material,
the radiator having a plurality of projections which are arranged outside a region opposite to the semiconductor element and which protrude toward the substrate.

9. The method according to claim 8, wherein in the heating the heat conducting material, the heat conducting material flows out of the region opposite to the semiconductor element and is held among the plurality of projections.

10. A semiconductor device comprising:
a substrate;
a semiconductor element placed over the substrate;
a heat conducting material placed over the semiconductor element; and
a radiator placed over the heat conducting material, the radiator having a net-like wire member placed outside a region opposite to the semiconductor element.

11. The semiconductor device according to claim 10, wherein the net-like wire member is placed along a circumference of the region opposite to the semiconductor element.

12. The semiconductor device according to claim 10 further comprising electronic components arranged outside the semiconductor element over the substrate, wherein the net-like wire member is selectively placed over the electronic components so as not to touch the electronic components.

13. The semiconductor device according to claim 10, wherein positions of ends of the net-like wire member on a semiconductor element side correspond to positions of ends of the semiconductor element.

14. The semiconductor device according to claim 10, wherein the heat conducting material is placed between the semiconductor element and the region opposite to the semiconductor element and in the net-like wire member.
